(19) United States
(12) Patent Application Publication
(10) Pub. No.: US 2011/0267748 A1
(43) Pub. Date: Nov. 3, 2011

(54) Case Configured to Removably Couple to a Portable Electrical Device and Method of Providing and Use Thereof

(75) Inventors: Steven Lane, Orange, CA (US); David A. Kleeman, Marina del Rey, CA (US); Oliver Duncan Seil, Pasadena, CA (US); Colin Greenidge, Thousand Oaks, CA (US); Henry Law, Orange, CA (US); Juliana S. Hung, Pasadena, CA (US); Ravi Itiravivong, Evanston, IL (US); Takuya Idehara, Los Angeles, CA (US); Aaron Richard Sevier, Santa Monica, CA (US); Jonny Yuan, Garden Grove, CA (US)

(73) Assignee: Belkin International, Inc., Playa Vista, CA (US)

(21) Appl. No.: 13/096,519

(22) Filed: Apr. 28, 2011

Related U.S. Application Data
(60) Provisional application No. 61/329,091, filed on Apr. 28, 2010.
(60) Provisional application No. 61/357,523, filed on Jun. 22, 2010.

(51) Int. Cl. H05K 7/00

(52) U.S. Cl. 361/679.01

(57) ABSTRACT

Some embodiments concern a holder for an electrical device. The holder can include: (a) a cover configured to couple to the electrical device, the cover having: (1) a front portion; (2) a back portion opposite the front portion; (3) one or more side portions; and (b) a holding mechanism coupled to the back portion of the cover such that the holding mechanism is rotatable at least ninety degrees relative to the back portion of the cover, the holding mechanism having: (1) a strap assembly configured to couple to the back portion of the cover; and (2) a strap configured to couple to the strap assembly. Other embodiments are disclosed.

### CROSS-REFERENCE TO RELATED APPLICATIONS

This application claims the benefit of U.S. Provisional Application No. 61/329,091, filed Apr. 28, 2010 and U.S. Provisional Application No. 61/357,523, filed Jun. 22, 2010. U.S. Provisional Application No. 61/329,091 and U.S. Provisional Application No. 61/357,523 are incorporated herein by reference.

### FIELD OF THE INVENTION

This invention relates generally to cases for electrical devices, and relates more particularly to such cases that provide access to and allow easy usage of electrical devices and methods of providing and using the same.

### DESCRIPTION OF THE BACKGROUND

The portable media player, cellar telephone, and portable computer market has changed dramatically in the past several years, and with such change, a new market for cases for portable media players, cellar telephones, and portable computers has developed. Recent trends have focused on the emergence of smart devices, which are electrical devices that incorporate features usually found in desktop and laptop computers, but not found in traditional handheld phones or media players.

Smart devices can include the merging of one or more of the following features: a personal data/digital assistant (PDA) and a cellular phone; a keyboard interface (e.g., a QWERTY keyboard), configured as either a touch screen or tactile keyboard; and the capability to receive/download and view audio/video files. Furthermore, smart devices can: run operating system software providing a standardized interface and platform for application developers; include advanced features like e-mail, Internet access, and e-book reader capability; and/or include a built-in full keyboard or external universal serial bus (USB) keyboard and video graphics array (VGA) connector. In other words, smart devices can be considered miniature computers that have telephone or wireless networking capabilities. Examples of smart devices include the iPhone® product and iPad® product by Apple Inc. of Cupertino, Calif. Another example of a smart device is the Blackberry® product by Research In Motion (RIM) of Waterloo, Ontario, Canada.

While smart devices provide great benefits to their users, actually using a smart device can sometimes be challenging. For example, if a user does not have a surface on which to rest the smart device, the user must hold the device in one hand while trying to operate the smart device with the other hand. Many smart devices are not designed to be easily held in one hand and operated using the other hand. In these cases, the user will have to hold the smart device at awkward angles against his body or risk dropping and damaging the expensive smart device.

Accordingly, a need exists for a case for an electrical device (e.g., a smart device) that both protects the electrical device and allows easy operation of the electrical device in various situations.

### BRIEF DESCRIPTION OF THE DRAWINGS

To facilitate further description of the embodiments, the following drawings are provided in which:

FIG. 1 illustrates a back, top, left isometric view of a case, according to a first embodiment;

FIG. 2 illustrates a front, bottom isometric view of the case of FIG. 1 holding a portable electrical device, according to the first embodiment;

FIG. 3 illustrates a partially exploded, back, top, right isometric view of the case of FIG. 1, according to the first embodiment;

FIG. 4 illustrates a bottom view of the case of FIG. 1, according to the first embodiment;

FIG. 5 illustrates a top view of the case of FIG. 1, according to the first embodiment;

FIG. 6 illustrates a left side view of the case of FIG. 1, according to the first embodiment;

FIG. 7 illustrates a right side view of the case of FIG. 1, according to the first embodiment;

FIG. 8 illustrates an exploded view of a body and rotatable elements of the case of FIG. 1, according to the first embodiment;

FIG. 9 illustrates a bottom view of a portion of a holding assembly of the case of FIG. 1, according to the first embodiment;

FIG. 10 illustrates a top view of the portion of the holding assembly of FIG. 9, according to the first embodiment;

FIG. 11 illustrates cross-sectional views along line 11-11 (FIG. 1) of the case of FIG. 1, according to the first embodiment;

FIG. 12 illustrates an exploded view of a portion of a case, according to a second embodiment;

FIG. 13 illustrates a back, bottom, right isometric view of a case, according to a third embodiment;

FIG. 14 illustrates a back, top, right isometric view of the case of FIG. 13, according to the third embodiment;

FIG. 15 illustrates a right side view of the case of FIG. 13, according to the third embodiment;

FIG. 16 illustrates a front, right isometric view of the case of FIG. 13 resting on a surface, according to the third embodiment;

FIG. 17 illustrates a back, right isometric view of the case of FIG. 13 resting on the surface of FIG. 16, according to the third embodiment;

FIG. 18 illustrates an exploded view of a holding mechanism of the case of FIG. 13, according to the third embodiment;

FIG. 19 illustrates a partially exploded, back, top, right isometric view of a case, according to a fourth embodiment;

FIG. 20 illustrates a flow chart for an embodiment of a method of providing a case for a portable electrical device;

FIG. 21 illustrates a flow chart for an embodiment of a method of using a case with a portable electrical device;

FIG. 22 illustrates an example of a first holding assembly coupled to at least part of the hand of a user, according to an embodiment;

FIG. 23 illustrates an example of the case of FIG. 22 coupled to at least part of the hand of the user and the electrical device before the body and electrical device are rotated, according to an embodiment;

FIG. 24 illustrates an example of the case of FIG. 22 coupled to at least part of the hand of the user and the electrical device after the body of the case and the electrical device have been rotated, according to an embodiment;

FIG. 25 illustrates an example of a first holding assembly of the case of FIG. 22 being uncoupled from the hand of the user, according to an embodiment;

FIG. 26 illustrates an example of the first holding assembly of the case of FIG. 22 being uncoupled from the body of the case, according to an embodiment;

FIG. 27 illustrates an example of the second holding assembly of the case in an unextended position, according to an embodiment;

FIG. 28 illustrates an example of the second holding assembly of a case in a first extended position, according to an embodiment;

FIG. 29 illustrates an example of the hook of the second holding assembly being extended away from the first hook assembly, according to an embodiment;

FIG. 30 illustrates an example of the second holding assembly in a second extended position, according to an embodiment;

FIG. 31 illustrates a partially exploded, back, right isometric view of a case being held by a user, according to a fifth embodiment;

FIG. 32 illustrates a back view of the case of FIG. 31 being held by the user, according to the fifth embodiment; and

FIG. 33 illustrates a back, right isometric view of the case of FIG. 31 resting on a surface, according to the fifth embodiment.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled but not be mechanically or otherwise coupled; two or more mechanical elements may be mechanically coupled, but not be electrically or otherwise coupled; two or more electrical elements may be mechanically coupled, but not be electrically or otherwise coupled. Coupling may be for any length of time, e.g., permanent or semi-permanent or only for an instant.

“Electrical coupling” and the like should be broadly understood and include coupling involving any electrical signal, whether a power signal, a data signal, and/or other types or combinations of electrical signals. “Mechanical coupling” and the like should be broadly understood and include mechanical coupling of all types.

The absence of the word “removably,” “removable,” and the like near the word “coupled,” and the like does not mean that the coupling, etc. in question is or is not removable.

### DETAILED DESCRIPTION OF EXAMPLES OF EMBODIMENTS

Some embodiments concern a holder for an electrical device. The holder can include: (a) a cover configured to couple to the electrical device, the cover having: (1) a front portion; (2) a back portion opposite the front portion; (3) one or more side portions; and (b) a holding mechanism coupled to the back portion of the cover such that the holding mechanism is rotatable at least ninety degrees relative to the back portion of the cover, the holding mechanism having: (1) a strap assembly configured to couple to the back portion of the cover; and (2) a strap configured to couple to the strap assembly. The back portion has a substantially circular aperture. At least a first portion of the strap assembly has a substantially circular shape. The at least the first portion of the strap assembly is configured to couple to the cover at the substantially circular aperture of the back portion. The holding mechanism is configured to rotate relative to the back portion of the cover such that the at least first portion of the strap assembly is rotatable around the substantially circular aperture of the back portion. The holding mechanism is further configured such that at least a part of a hand of a user of the electrical device can slide between the strap assembly and the strap to removably couple the holding mechanism to the at least the part of the hand of the user of the electrical device. The one or more side portions are configured such that the one or more side controls of the electrical device are accessible to the user when the cover is coupled to the electrical device. The cover is configured such that the screen of the electrical device is accessible to the user when the cover is coupled to the electrical device. The cover is configured such that the front portion of the cover is adjacent to the back of the electrical device when the cover is coupled to the electrical device.

Still other embodiments concern a case configured to removably couple to a portable electrical device. The case is configured to couple to at least part of a hand of a user of the portable electrical device. The case including: (a) a body configured to removably coupleable to the portable electrical device; (b) a holding assembly coupled to the body, the holding assembly having: (1) a first coupling assembly configured to coupled the body; and (2) a hand coupling assembly coupled to the first coupling assembly and configured to removably couple to the at least the part of the hand of the user of the portable electrical device. At least a portion of the first coupling assembly is substantially circular-shaped. The body having: a back side with a first substantially circular aperture; and a front side opposite the back side. The at least the portion of the first coupling assembly that is substantially circular-shaped is removably coupled to the body at the first substantially circular aperture of the back side of the body. The holding assembly is coupled to the body such that the holding assembly is rotatable at least ninety degrees relative to the body and the portable electrical device when the body is coupled to the portable electrical device and the body is further coupled to the holding assembly. The holding assembly is further configured such that the at least the part of the hand of the user of the portable electrical device can slide into the holding assembly to removably couple the holding assembly to the at least the part of the hand of the user of the portable electrical device. The body is configured to couple to the portable electrical device such that the screen of the portable electrical device is useable when the body is coupled to the portable electrical device and the back side of the portable electrical device is adjacent to the front side of the body.

Yet other embodiments concern a method of providing a case for a portable electrical device. The method including: providing a body configured to removably coupleable to the portable electrical device, the body comprising: a front side opposite the back side; a back side with a first substantially circular aperture, wherein the body is configured to couple to the portable electrical device such that the screen of the portable electrical device is useable when the body is coupled to the portable electrical device and the back side of the portable electrical device is adjacent to the front side of the body; providing a holding assembly configured such that the at least the part of the hand of the user of the portable electrical device can slide into the holding assembly to removably couple the holding assembly to the at least the part of the hand of the user of the portable electrical device, the holding assembly having: a first coupling assembly coupled the body wherein the first coupling assembly comprises at least a substantially circular-shaped portion; and a hand coupling assembly coupled to the first coupling assembly and configured to removably couple to the at least the part of the hand of the user of the portable electrical device; and coupling the holding assembly to the body by coupling the at least the substantially circular-shaped portion of the first coupling assembly of the holding assembly to the body at the first substantially circular aperture of the back side of the body and such that the holding assembly is rotatable at least ninety degrees relative to the body.

Additional embodiments concern a method of using a case with a portable electrical device. The case comprising a body and a first holding assembly with the first holding assembly configured to couple to at least a part of a hand of a user. The method including: coupling the body of the case to the portable electrical device; coupling the body to the first holding assembly; coupling at least part of the hand of the user to the first holding assembly; and rotating the body and the portable electrical device at least ninety degrees relative to the first holding assembly.

Still further embodiments concern a case configured to removably couple to a portable electrical device. The case including: (a) a body configured to removably couple to the portable electrical device; (b) one or more rotatable elements coupled to the body; and (c) a holding assembly coupled to the one or more rotatable elements and configured to couple to at least part of a hand of a user. The one or more rotatable elements are couple to the body such that the at least a part of the one or more rotatable elements and the holding assembly are rotatable at least ninety degrees relative to the body. The body comprises a front side and a back side opposite the front side. The holding assembly is located at the back side of the body. A screen of the portable electrical device is located at the front side of the body when the body is coupled to the portable electrical device.

Yet additional embodiments concern a holder for an electrical device. The holder having: (a) an inner cover configured to couple to the electrical device; (b) at least one first ring assembly coupled to the inner cover, the at least one inner ring assembly having: (1) a base portion configured to couple to the body; (2) one or more rotatable portions coupled to the base portion such that the rotatable portions are rotatable three hundred and sixty degrees relative to the body and the base portion; (c) an outer cover coupled to the inner cover and the at least one inner ring assembly; (d) a holding mechanism coupled to the one or more rotatable portions of the at least one ring assembly such that the holding mechanism is rotatable at least three hundred and sixty degrees relative to the outer cover, the holding mechanism further configured to removably couple to at least part of a hand of a user of the electrical device.

Still another embodiment concerns a method of providing a case for a portable electrical device. The method including: (a) providing a body configured to couple to the portable electrical device; (b) providing one or more rotatable elements; (c) providing at least one holding assembly configured to couple to at least part of a hand of a user and further configured to couple to the one or more rotatable elements; (d) providing a filler cap configured to couple to the one or more rotatable elements when the at least one holding assembly is not coupled to the one or more rotatable elements; and (e) coupling the one or more rotatable elements to the body such that the at least the at least one holding assembly is rotatable at least approximately ninety degrees relative to the body when the at least one holding assembly is coupled to the one or more rotatable elements.

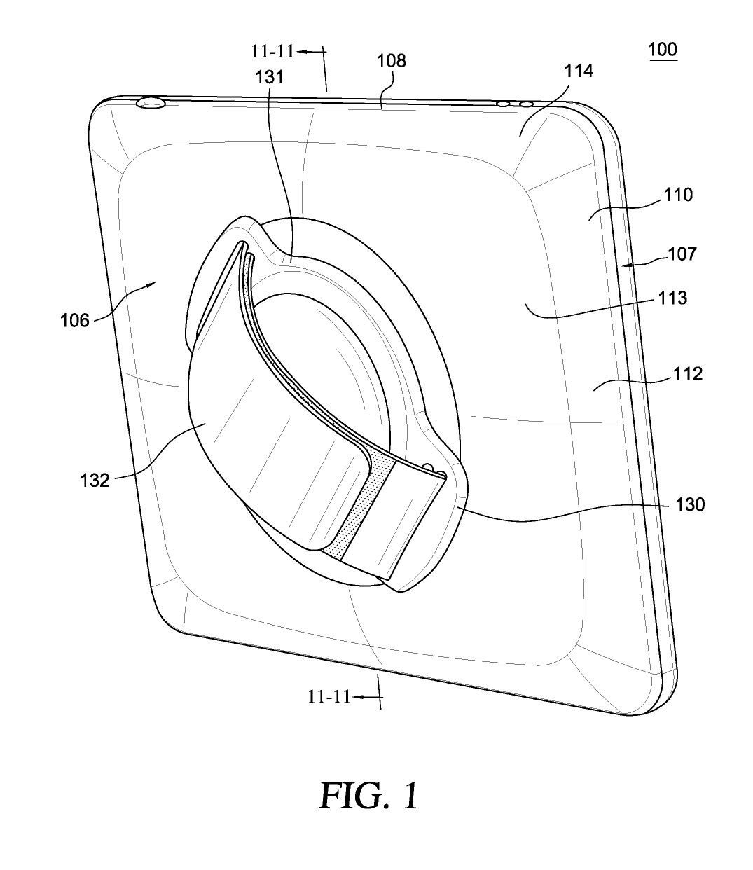

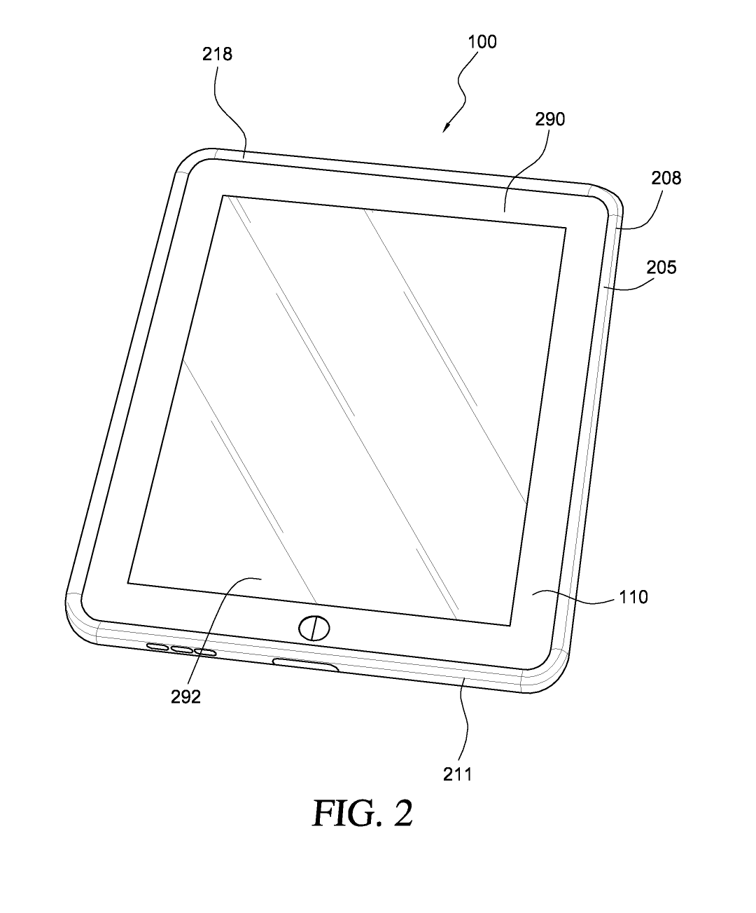

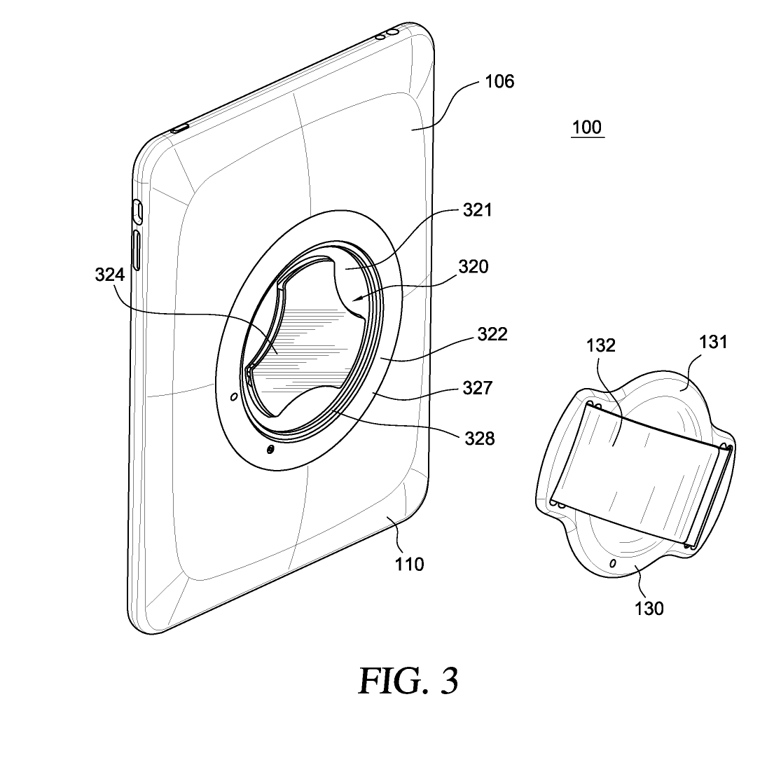

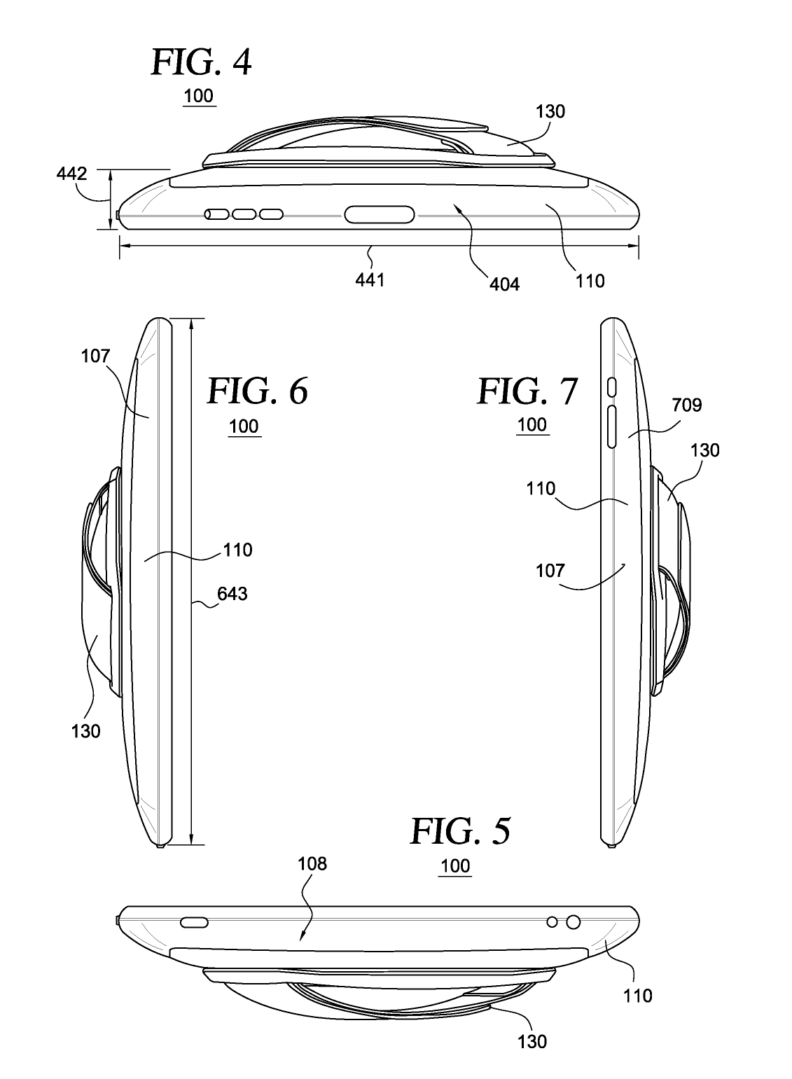

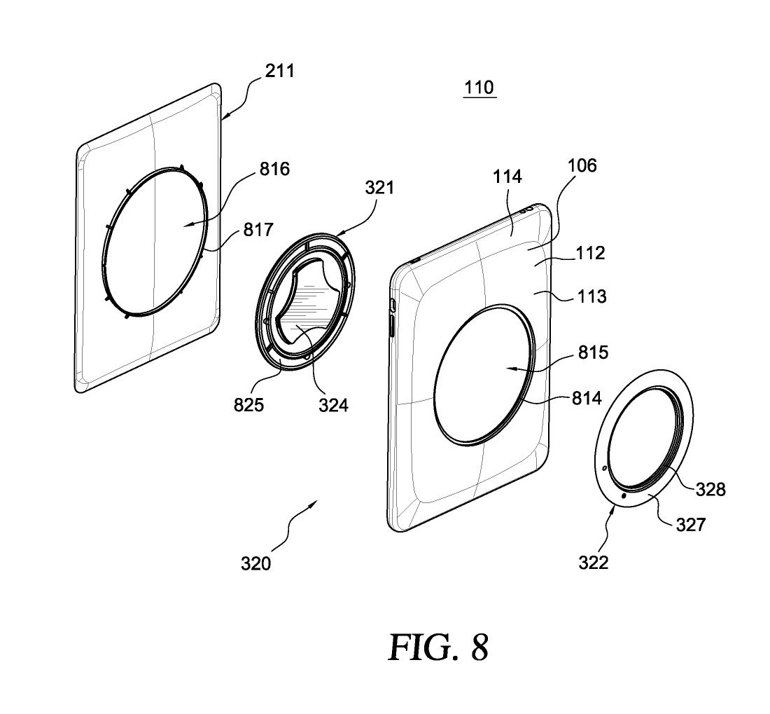

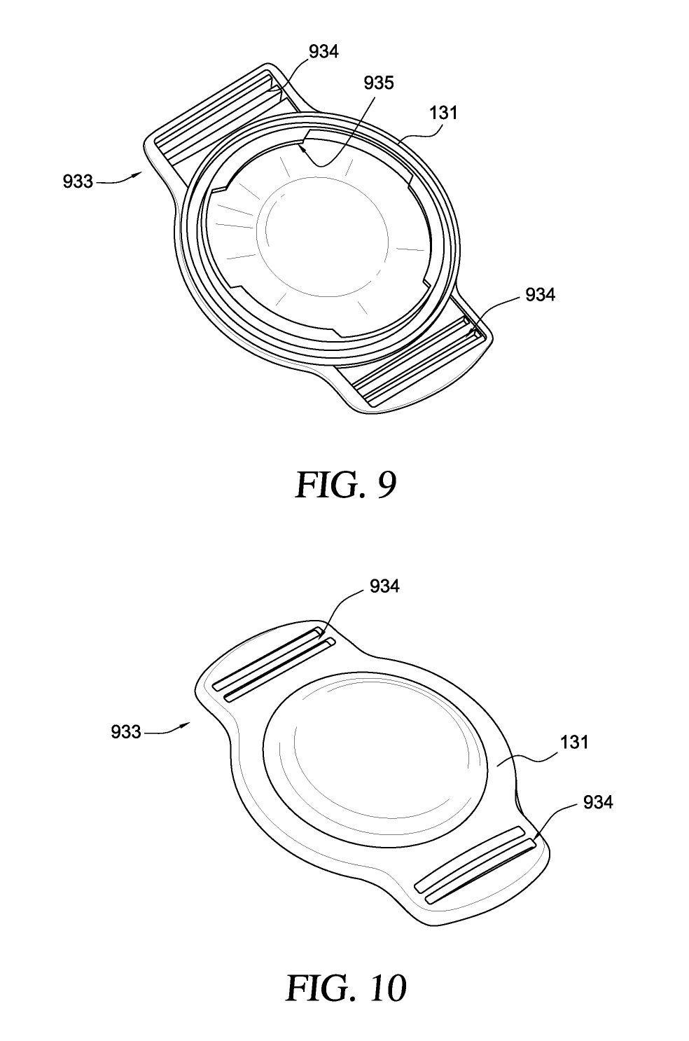

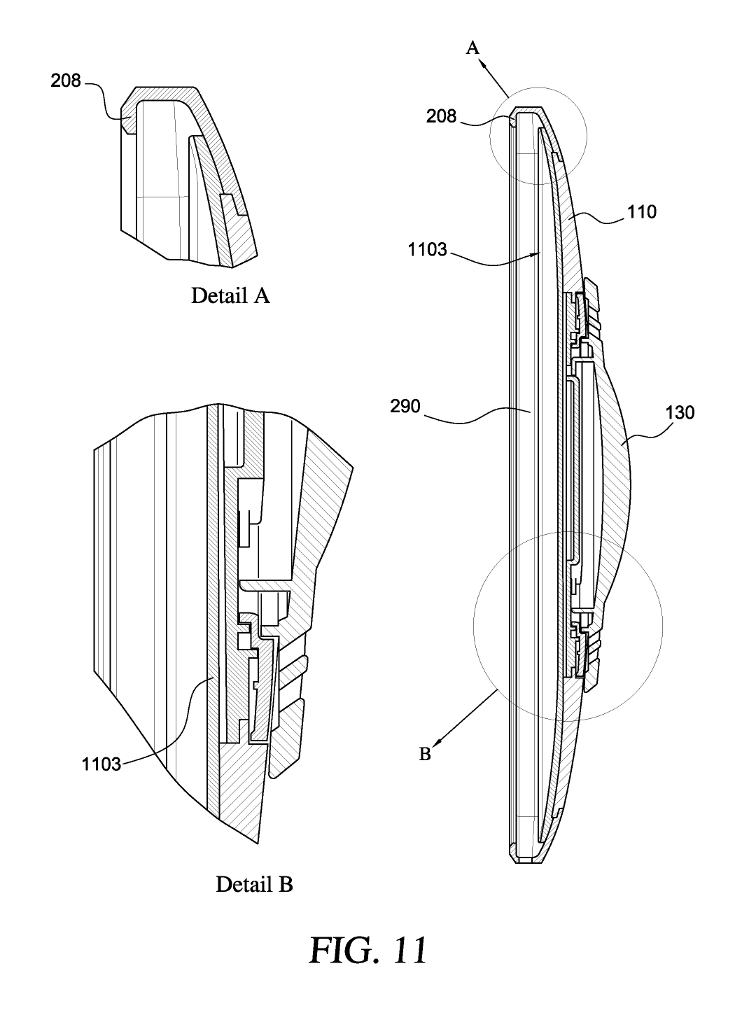

Turning to the drawings, FIG. 1 illustrates a back, top, left isometric view of a case 100, according to a first embodiment. FIG. 2 illustrates a front, bottom isometric view of case 100 holding a portable electrical device 290, according to the first embodiment. FIG. 3 illustrates a back, top, right isometric view of case 100, according to the first embodiment. FIG. 4 illustrates a bottom view of case 100, according to the first embodiment. FIG. 5 illustrates a top view of case 100, according to the first embodiment. FIG. 6 illustrates a left side view of case 100, according to the first embodiment. FIG. 7 illustrates a right side view of case 100, according to the first embodiment. FIG. 8 illustrates an exploded view of a body 110 and rotatable elements 320 of case 100, according to the first embodiment. FIG. 9 illustrates a bottom view of holding assembly 130 of case 100, according to the first embodiment. FIG. 10 illustrates a top view of holding assembly 130 of case 100, according to the first embodiment. FIG. 11 illustrates cross-sectional views along line 11-11 (FIG. 1) of case 100, according to the first embodiment.

In some examples, case 100 can be configured to removably couple to portable electrical device 290 (FIG. 2). Case 100 can also be considered a holder for portable electrical device 290. Case 100 is merely exemplary and is not limited to the embodiments presented herein. Case 100 can be employed in many different embodiments or examples not specifically depicted or described herein.

In some embodiments, portable electrical device 290 can be an electrical device configured to produce and receive electrical signals. For example, portable electrical device 290 can be a cellular (or mobile) phone, a laptop computer, an audio playback device, a portable AM (amplitude modulated) and FM (frequency modulated) radio, a satellite radio, a portable CD (compact disk) player, a data storage device, an audio player, an audio-visual player, and/or a portable media (e.g., MP3) player. For example, portable electrical device 290 can be an electrical device manufactured by Research in Motion Limited (e.g., the Blackberry® device), Palm, Inc. (e.g., the Palm® device), or Apple Computer, Inc. (e.g., the iPod® MP3 player, the iTouch® device, the iPad® device, and/or the iPhone® device).

In some examples, case 100 can include: (a) a body 110 (i.e., a cover) configured to removably couple to portable electrical device 290 (FIG. 2); (b) one or more rotatable elements 320 (FIG. 3) coupled to body 110; and (c) a holding assembly 130 (i.e., a holding mechanism). In some examples, rotatable elements 320 are couple to body 110 such that at least holding assembly 130 and a part of rotatable elements 320 are rotatable at least approximately ninety degrees relative to body 110. In the same or different examples, rotatable elements 320 are coupled to body 110 such that at least holding assembly 130 and a part of rotatable elements 320 are rotatable at least approximately one hundred and eighty degrees, approximately two hundred and seventy degrees, and/or approximately three hundred and sixty degrees relative to body 110. In the same or different examples, rotatable elements 320 can be considered part of body 110.

In some examples, body 110 can have: (a) a front portions (or sides) 205 (FIGS. 2) and 1103 (FIG. 11); (b) a back portion (or side) 106 opposite front portion 205; and (c) one or more side portions 107, 108, 404, and 709 (FIGS. 1, 1, 4, and 6, respectively). In some examples, side portions 107, 108, 404, and 609 are configured such that the one or more side controls of electrical device 290 are accessible to the user when body 110 is coupled to electrical device 290. Body 110 is further configured such that screen 292 of electrical device 290 is accessible to the user when body 110 is coupled to electrical device 290. Body 110 is configured such that front portion 1103 is adjacent to a back of electrical device 290 when body 110 is coupled to electrical device 290, as shown in FIG. 11.

Body 110 can include: (a) inner cover 211; and (b) an outer cover 112. Outer cover 112 can be coupled to inner cover 211. In some examples, outer cover 112 can be glued, welded, bonded, or otherwise attached to inner cover 211. In another embodiment, the inner and outer covers can be a single, integral piece. In some embodiments, regardless of whether body 110 has separate inner and outer covers or a single cover, body 110 has a width 441 (FIG. 4) in the range of approximately 150 millimeters (mm) to approximately 250 mm (e.g., 198 mm). Body 110 can also have a length 643 (FIG. 6) in a range of approximately 200 mm to approximately 300 mm (e.g., 250 mm). Furthermore, body 110 can have a depth 442 in the range of approximately 22 mm to approximately 32 mm (e.g., 27 mm).

Outer cover 112 can have an aperture 815 (FIG. 8). Similarly, inner cover 211 can also have an aperture 816. In some embodiments, apertures 815 and 816 can be substantially circular in shape. As will be described in detail below, apertures 815 and/or 816 can be sized and shaped to couple to rotatable elements 320 (FIG. 3) and holding assembly 130 (FIG. 1).

In some examples, inner cover 211 can be configured to couple to portable electrical device 290. Body 110 can be further configured such that portable electrical device 290 can be located at front side 218 (FIG. 3) when body 110 is coupled to portable electrical device 290. For example, inner cover 211 can be configured to have a rim 208 that can wrap around at least a portion of a perimeter of portable electrical device 290 to removably couple portable electrical device 290 to body 110. In other examples, other coupling mechanisms can be used (e.g., a hook and look fastener system (i.e., Velcro® fasteners), a pocket system, or a snap fastener system).

In various embodiments, as illustrated in FIG. 8, in addition to aperture 815, outer cover 112 can include: (a) a center portion 113; and (b) an outer perimeter portion 114. Outer perimeter portion 114 can encircle center portion 113 and form the exterior edge of outer cover 112. Aperture 815 can be located in center portion 113. In some examples, center portion 113 and outer perimeter portion 114 can be co-molded to be integral with each other. Center portion 113 and inner cover 211 can be composed of polycarbonate and/or other materials. Outer perimeter portion 114 can be composed of TPU (thermoplastic polyurethane), and/or other materials. In other examples, center portion 113, inner cover 211, and outer perimeter portion 114 can be composed of the same material.

As illustrated in FIGS. 3 and 8, rotatable elements 320 (i.e., at least one connector mechanism or a ring assembly) can include: (a) an inner connector mechanism 321 configured to couple to body 110; and (b) an outer connector mechanism 322 configured to couple to outer cover 112. In some examples, inner connector mechanism 321 can be considered at least one first ring assembly, and outer connector mechanism 322 can be considered at least one second ring assembly.

In some examples, inner connector mechanism 321 can be configured to couple to inner cover 211 and outer cover 112. For example, inner connector mechanism 321 can be at least partially located between inner cover 211 and outer cover 112. In the same or different example, inner connector mechanism 321 can couple to inner cover 211 by at least partially being located inside of aperture 816. Similarly, inner connector mechanism 321 can be coupled to outer cover 112 by at least partially being located inside of aperture 815. In various embodiments, inner cover 211 can include a rim 817 at the edge of aperture 816 to which inner connector mechanism 321 can couple, and/or outer cover 112 can include rim 814 at the edge of aperture 815 to which outer connector mechanism 322 can couple.

Inner connector mechanism 321 can include: (a) a base portion 825 coupled to body 110; and (b) one or more rotatable portions 324 coupled to base portion 825 such that rotatable portions 324 are rotatable relative to body 110 and base portion 825. As will be described in detail below, rotatable portions 324 are configured to be removably coupled to holding assembly 130 (FIGS. 1 and 3). In some embodiments, base portion 825 can be considered to be substantially immobile relative to inner cover 211 and outer cover 112.

Outer connector mechanism 322 can be at least partially coupled to back side 106. In some examples, outer connector mechanism 322 can include: (a) a perimeter portion 327; and (b) a rim portion 328 coupled to perimeter portion 327 and extending away from perimeter portion 327. In various examples, outer connector mechanism 322 is configured such that perimeter portion 327 is coupled to back side 106, and interior rim portion 328 is coupled to edge 814 of aperture 815.

Inner connector mechanism 321 can be coupled to outer connector mechanism 322. In various embodiments, inner connector mechanism 321 can be glued, welded, bonded, or otherwise attached to outer connector mechanism 322. In many examples, rim portion 328 can be glued, welded, bonded, or otherwise attached to base portion 825. In other examples, inner connector mechanism 321 and outer connector mechanism 322 are not coupled together. Rather, inner connector mechanism 321 and outer connector mechanism 322 can be coupled to inner cover 211 and outer cover 112 of body 110.

As shown in FIGS. 1 and 3, holding assembly 130 can be configured to removably couple to body 110 via rotatable elements 320 and further configured to removably couple to at least part of a hand of a user of electrical device 290 (FIG. 2). Holding assembly 130 can include: (a) a strap assembly 131; and (b) a strap 132 configured to removably couple to strap assembly 131.

Strap assembly 131 can be configured to removably couple to rotatable elements 320. In some examples, strap assembly 131 can include a coupling mechanism 935 (FIG. 9) that is configured to couple to rotatable portions 324. In various embodiments, rotatable portions 324 can snap into coupling mechanism 935. In other embodiments, other coupling mechanisms can be used to couple holding assembly 130 to rotatable portions 324 and/or body 110.

In some examples, as shown in FIG. 9, coupling mechanism 935 can have a substantially circular shape. Coupling mechanism 935 can couple to cover outer cover 112 at aperture 815. Holding assembly 130 (FIGS. 1 and 3) can be configured to rotate relative to back portion 106 such that at least a first portion of strap assembly 131 is rotatable around aperture 815 (FIG. 8).

In some examples, holding assembly 130 is configured such that at least the part of the hand of the user (e.g., one or more fingers, one or more fingers and one or more knuckles, and/or a palm) can slide between strap assembly 131 and strap 132 to removably couple holding assembly 130 to the hand of the user of electrical device 290.

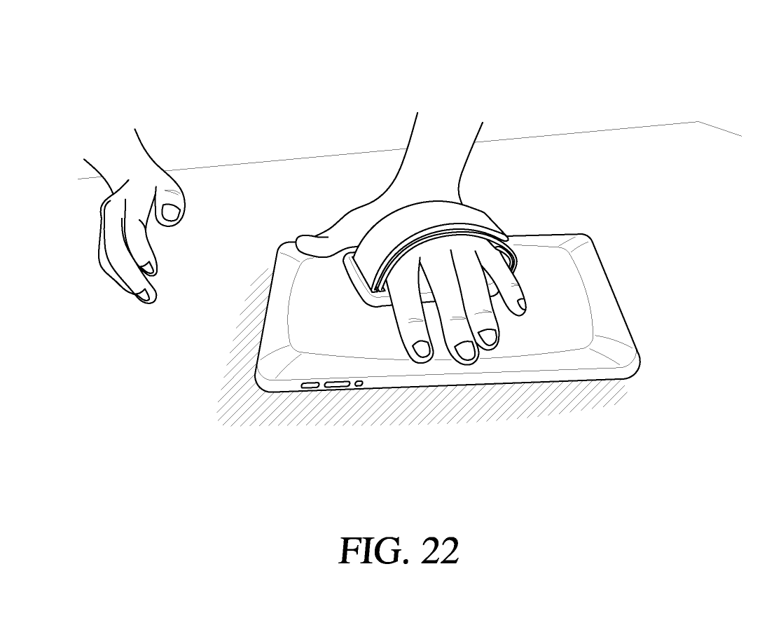

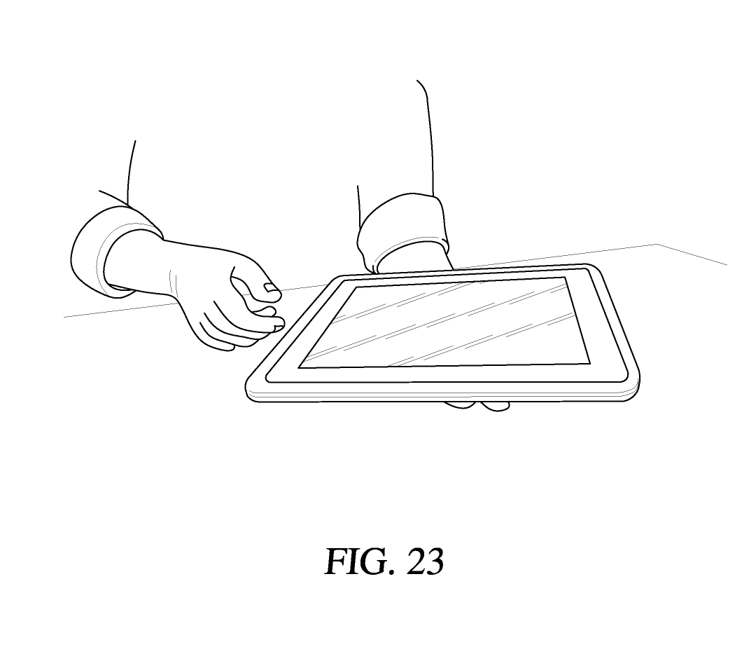

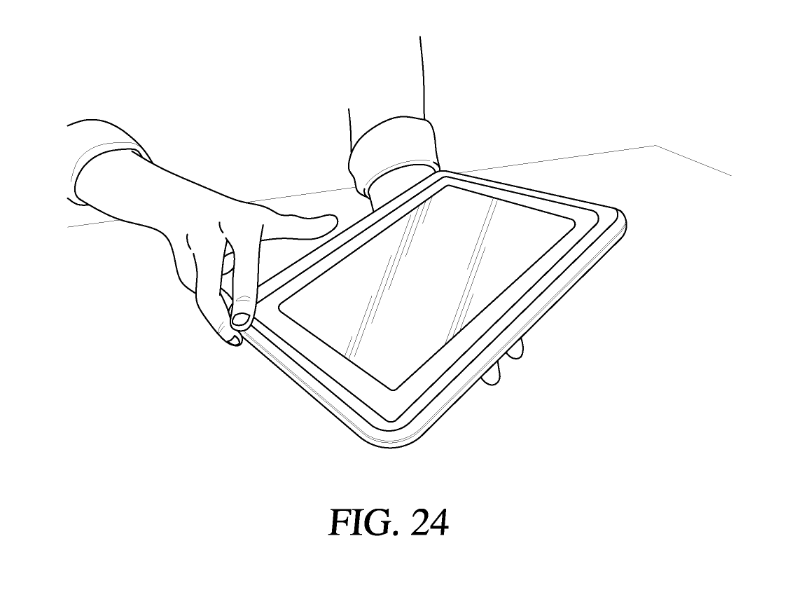

In various embodiments, when part of the hand of the user is coupled to holding assembly 130, the user can easily use electrical device 290. For example, a user can place electrical device 290 in case 100 and slide part of his hand between strap assembly 131 and strap 132. At this point, the user is securely holding electrical device 290 with one hand, as shown in FIGS. 22-24. Holding electrical device 290 in one hand using case 100 frees the other hand to operate electrical device 290. That is, the other hand of the user is free to operate electrical device 290 without the danger of accidently dropping electrical device 290.

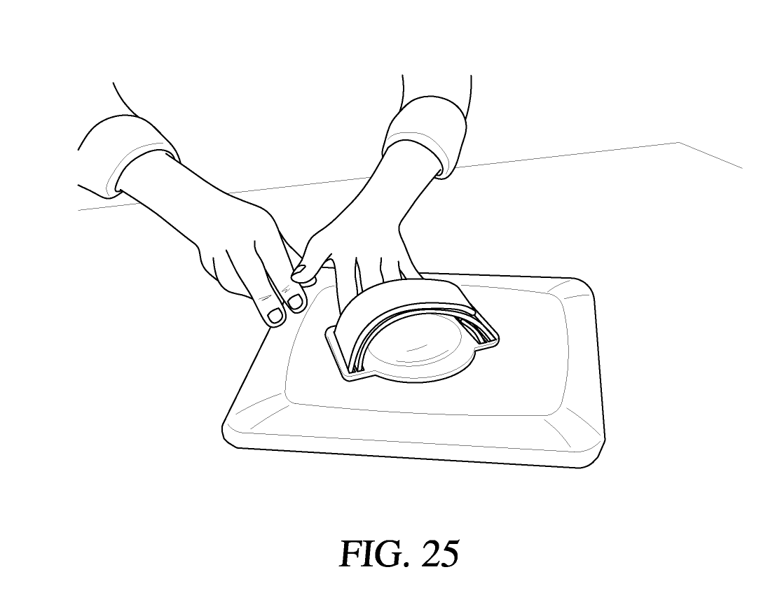

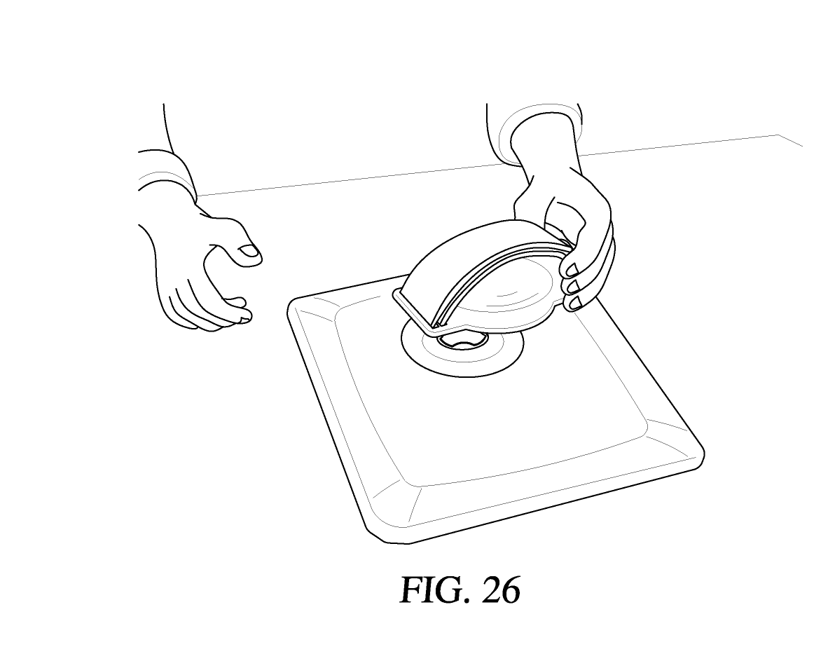

As described above, holding assembly 130 is rotatable relative to body 110. When the part of the user's hand is coupled to holding assembly 130, body 110 can be rotated relative to holding assembly 130. Accordingly, the user can rotate the angle of electrical device 290 relative to the user's hand that is holding case 100. In same examples, electrical device 290 can be rotated up to approximately three hundred and sixty degrees relative to the hand of the user holding case 100. In the same or different examples, from the point of view of the user, electrical device 290 can be rotated between a portrait view and a landscape view, as shown in FIGS. 23-24.

In some examples, strap assembly 131 can include one or more coupling mechanisms 933 (FIG. 9) configured to couple to strap 132. In one example, coupling mechanisms 933 can be a belt system where strap 132 is looped though apertures 934 (FIG. 9) in strap assembly 131. In other examples, strap 132 can have a corresponding coupling mechanism. For example, strap assembly 131 and strap 132 can have a hook and look fastener system (e.g., Velcro® fasteners), a screw fastener system, a zipper fastener system, and/or a snap fastener system.

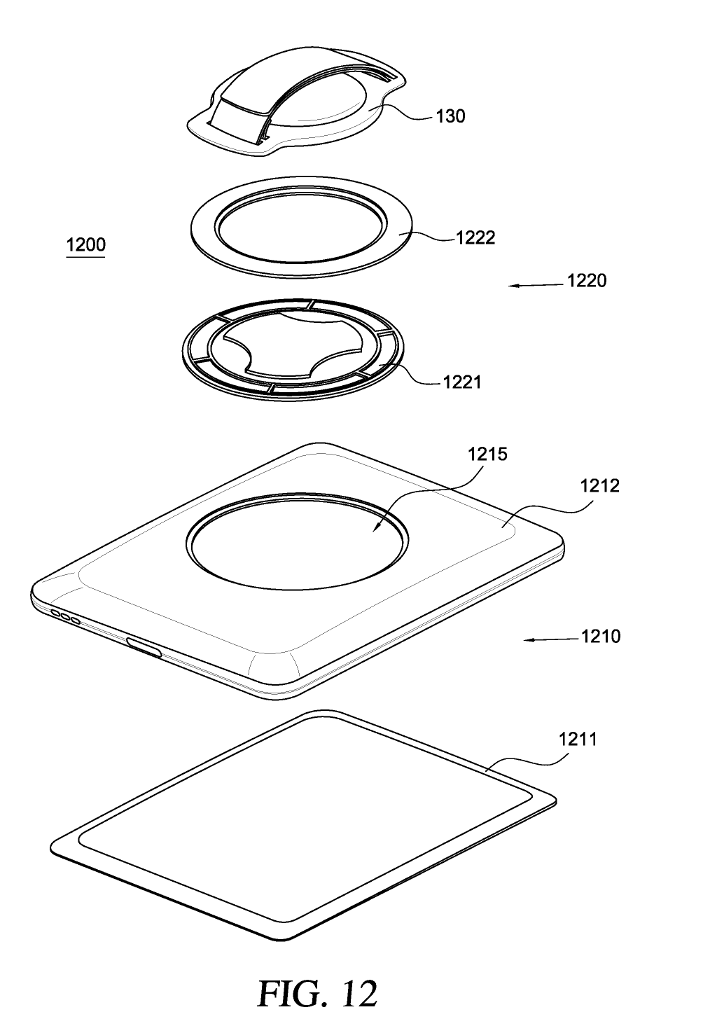

Turning to another embodiment, FIG. 12 illustrates an exploded view of case 1200, according to a second embodiment. Case 1200 is merely exemplary and is not limited to the embodiments presented herein. Case 1200 can be employed in many different embodiments or examples not specifically depicted or described herein. Case 1200 can be similar to case 100 in FIG. 1.

In some examples, case 1200 can include: (a) a body 1210 configured to removably couple to portable electrical device 290 (FIG. 2); (b) one or more rotatable elements 1220 coupled to body 1210; and (c) a holding assembly 130 (i.e., a holding mechanism). In some examples, rotatable elements 1220 are coupled to body 1210 such that at least holding assembly 130 and a part of rotatable elements 1220 are rotatable at least ninety degrees relative to body 1210. In the same or different examples, rotatable elements 1220 are coupled to body 1210 such that at least holding assembly 130 and a part of rotatable elements 1220 are rotatable at least one hundred and eighty degrees, two hundred and seventy degrees, and/or three hundred and sixty degrees relative to body 1210.

Body 1210 can include: (a) inner cover 1211; and (b) an outer cover 1212 with a depression 1215. Outer cover 1212 can be coupled to inner cover 1211. Rotatable elements 1220 can include: (a) an inner connector mechanism 1221 configured to couple to outer cover 1212; and (b) an outer connector mechanism 1222 coupled to outer cover 1212 and configured to couple to holding assembly 130. In some examples, inner connector mechanism 1221 and outer connector mechanism 1222 can be similar to inner connector mechanism 321 and outer connector mechanism 322 of FIG. 3.

In various embodiments, inner connector mechanism 1221 can be coupled to depression 1215. In some examples, one side of inner connector mechanism 1221 can rest on the bottom of depression 1215. Outer connector mechanism 1222 can be used to couple inner connector mechanism 1221 to body 1210 and/or provide a more aesthetic look for case 1200.

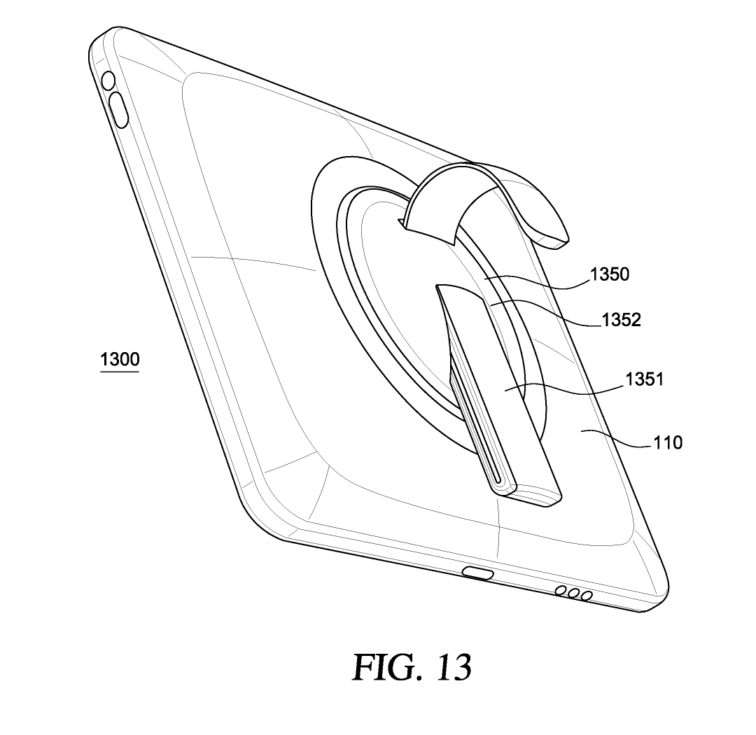

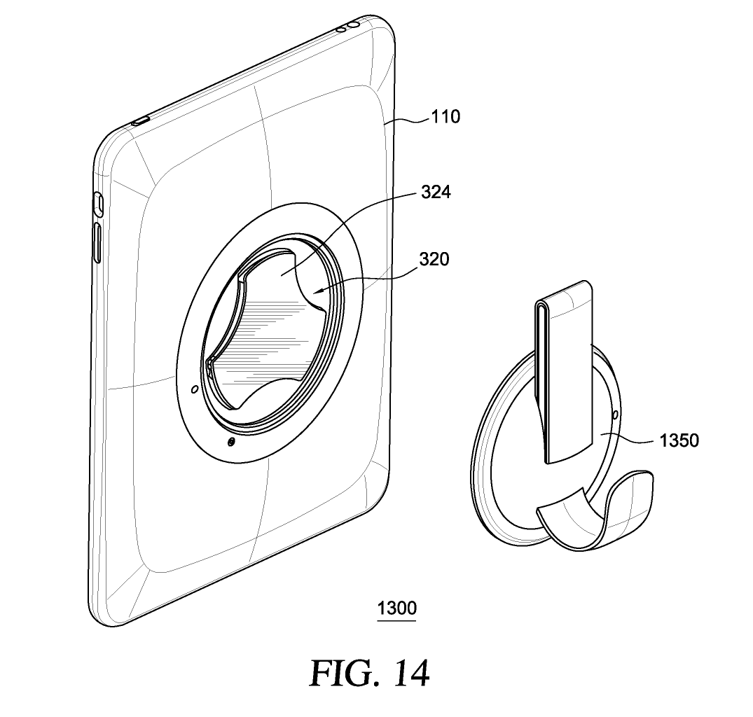

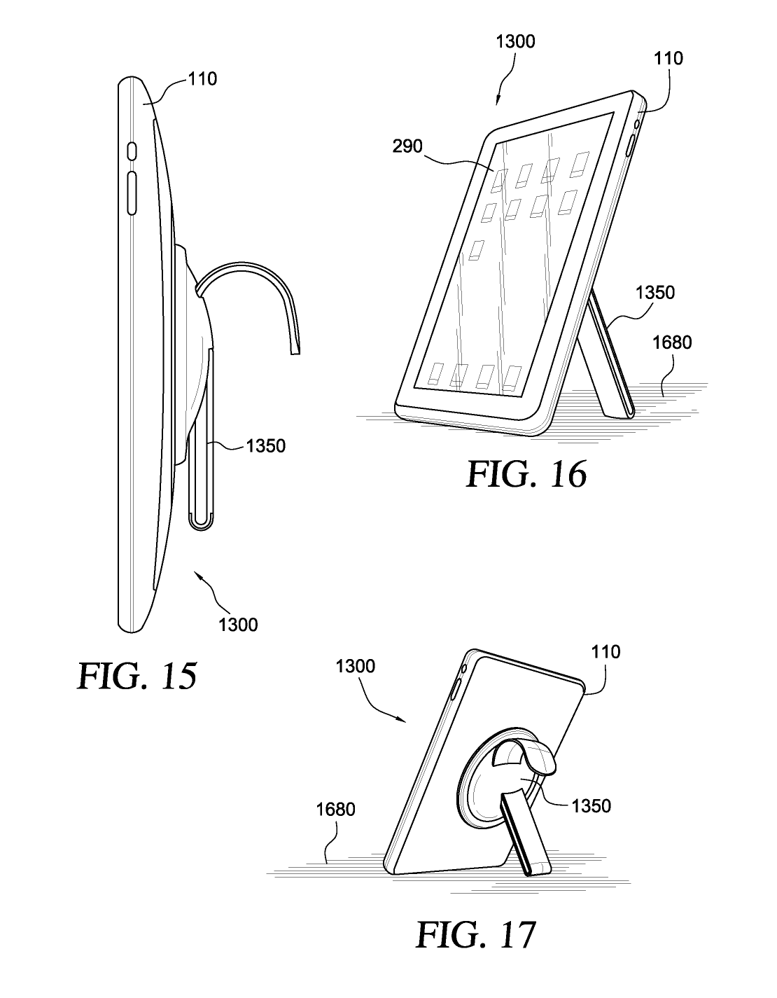

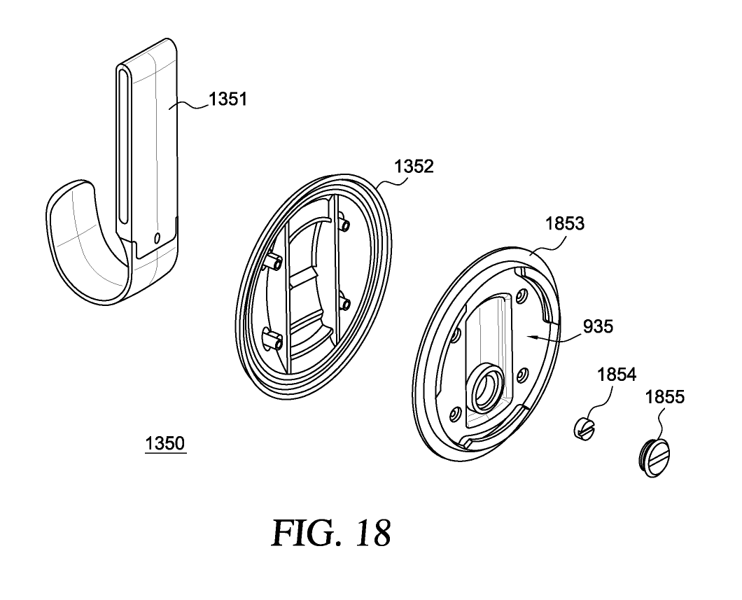

Turning to yet another embodiment, FIG. 13 illustrates a back, bottom, right isometric view of a case 1300, according to a third embodiment. FIG. 14 illustrates a back, top, right isometric view of case 1300, according to the third embodiment. FIG. 15 illustrates a right side view of case 1300, according to the third embodiment. FIG. 16 illustrates a front, top, right isometric view of case 1300 resting on a surface 1680, according to the third embodiment. FIG. 17 illustrates a back, top, right isometric view of case 1300 resting on surface 1680, according to the third embodiment. FIG. 18 illustrates an exploded view of holding assembly 1350 of case 1300, according to the third embodiment.

In some examples, case 1300 can be configured to removably couple to portable electrical device 290 (FIG. 16). Case 1300 can also be considered a holder for portable electrical device 290. Case 1300 is merely exemplary and is not limited to the embodiments presented herein. Case 1300 can be employed in many different embodiments or examples not specifically depicted or described herein. Case 1300 can be similar to cases 100 and 1200 of FIGS. 1 and 12, respectively.

In some examples, case 1300 can include: (a) body 110 configured to removably couple to portable electrical device 290 (FIG. 16); (b) one or more rotatable elements 320 (FIG. 14) coupled to body 110; and (c) a holding assembly 1350. In some examples, rotatable elements 320 are coupled to body 110 such that at least holding assembly 1350 and a part of rotatable elements 320 are rotatable at least ninety degrees relative to body 110. In the same or different examples, rotatable elements 320 are coupled to body 110 such that at least holding assembly 1350 and a part of rotatable elements 320 are rotatable at least one hundred and eighty degrees, two hundred and seventy degrees, and/or three hundred and sixty degrees relative to body 110.

In some examples, holding assembly 1350 (i.e., a holding mechanism) can include: (a) a hook 1351 (i.e., a stand); (b) an exterior hook cover 1352 coupled to hook 1351; (c) a hook base 1853 (FIG. 18) coupled to exterior hook cover 1352; and (d) one or more tension adjustment mechanisms 1854 and 1855 (FIG. 18) coupling hook base 1853 to exterior hook cover 1352. In various embodiments, hook 1351 can have a substantially J-shape. In some examples, hook 1351 can be coupled to exterior hook cover 1352 using tension adjustment mechanisms 1854 and 1855. Exterior hook cover 1352, hook base 1853, and/or tension adjustment mechanisms 1854 and/or 1855 can be considered a hook assembly (i.e., a stand assembly) in some embodiments.

Holding assembly 1350 can be configured to removably couple to rotatable elements 320. In some examples, holding assembly 1350 can include a coupling mechanism 935 (FIG. 18) that is configured to couple to rotatable portions 324 (FIG. 14). In various embodiments, rotatable portions 324 can snap into coupling mechanism 935. In other embodiments, other coupling mechanisms can be used to couple holding assembly 1350 to rotatable portions 324 and/or body 110.

Holding assembly 1350 can be configured such that hook 1351 can be placed in at least a first position and a second position relative to exterior hook cover 1352 and/or hook base 1853. For example, holding assembly 1350 can be configured such that hook 1351 can be placed in a first position relative to exterior hook cover 1352 and/or hook base 1853 (FIG. 18) such that at least a part of the hand of a user of electrical device 290 can be removably coupled to exterior hook cover 1352 and hook 1351 to removably couple the holding assembly 1350 to the part of the hand of the user. Hook cover 1352 has an outward bulge with a shape substantially complementary to a person's palm.

Holding assembly 1350 is further configured such that hook 1351 can be placed in a second position relative to exterior hook cover 1352 and/or hook base 1853 (FIG. 18) such that hook 1351 can rest on a surface 1680 to at least partially support the holder in an upright position, as shown in FIGS. 16, 17, and 27-30.

In some examples, the user can move hook 1351 from the first position to the second position by pulling hook 1351 away from exterior hook cover 1352. Similarly, the user can move hook 1351 from the second position to the first position by pushing hook 1351 toward the exterior hook cover. FIGS. 28-30 show the hook in the two positions.

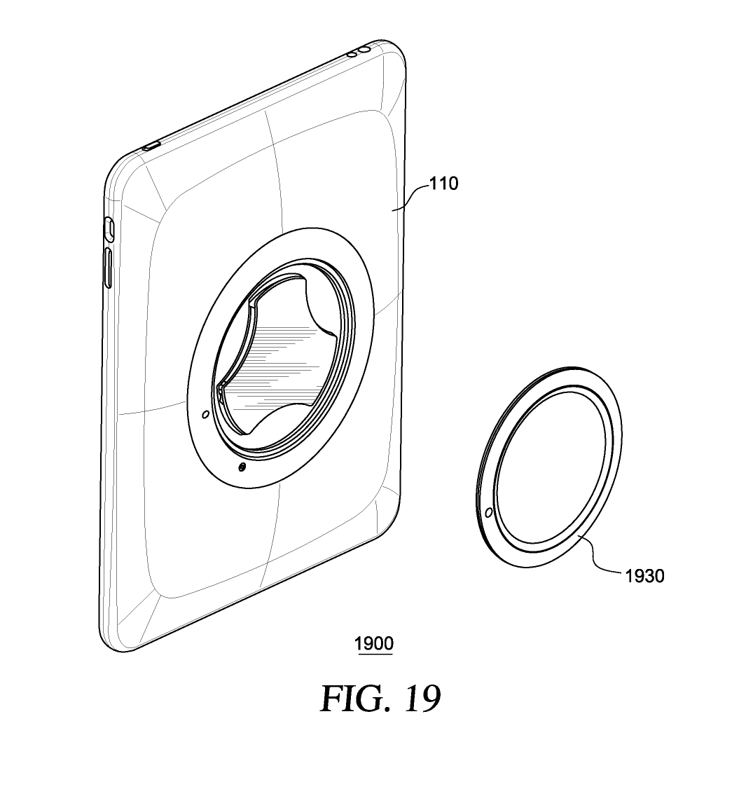

FIG. 19 illustrates a back, top, right isometric view of a case 1900, according to a fourth embodiment. Case 1900 can be similar to cases 100, 1200, and 1300 in FIGS. 1, 12, and 13, respectively. In this example, case 1900 includes: (a) a body 110; and (b) a filler cap 1930 configured to removably couple to body 110. In various embodiments, when holding assembly 130 (FIG. 1) or holding assembly 1350 are not coupled to body 110, filler cap 1930 can be coupled to body 110. Coupling filler cap 1930 to body 110 can provide a relatively smooth and uniform back surface to case 1900. In various embodiments, filler cap 1930 is rotatable relative to body 110. In other examples filler cap 1930 is immobile relative to body 110.

In some examples, a manufacturer, distributor, or retail seller can provide, distribute, or sell a body (e.g., body 110 or 1210 of FIGS. 1 and 12, respectively) with two or more of holding assembly 130 (FIG. 1), holding assembly 1350 (FIG. 13), and/or cap 1930.

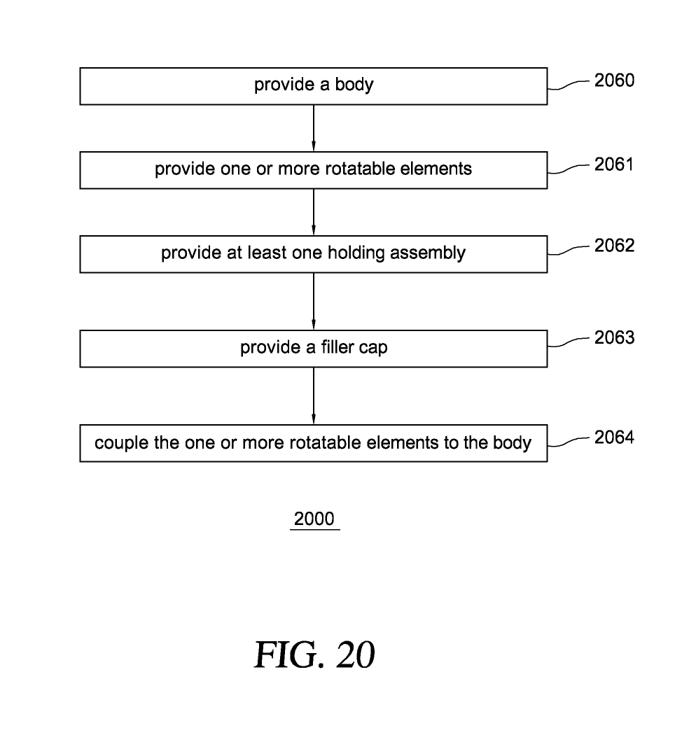

FIG. 20 illustrates a flow chart for an embodiment of a method 2000 of providing a case for a portable electrical device, according to an embodiment. Method 2000 is merely exemplary and is not limited to the embodiments presented herein. Method 2000 can be employed in many different embodiments or examples not specifically depicted or described herein. In some embodiments, the activities, the procedures, and/or the processes of method 2000 can be performed in the order presented. In other embodiments, the activities, the procedures, and/or the processes of method 2000 can be performed in any other suitable order. In still other embodiments, one or more of the activities, the procedures, and/or the processes in method 2000 can be combined or skipped.

Referring to FIG. 20, method 2000 includes an activity 2060 of providing a body. The body can be configured to couple to a portable electrical device. The body can have a front side and a back side opposite the front side. In some examples, the body can be similar or identical to body 110 of FIG. 1 or body 1210 of FIG. 12.

Method 2000 in FIG. 20 continues with an activity 2061 of providing one or more rotatable elements. In some examples, the rotatable elements can be similar or identical to rotatable elements 320 of FIG. 3 or rotatable elements 1220 of FIG. 12.

Subsequently, method 2000 of FIG. 20 includes an activity 2062 of providing at least one holding assembly configured to couple to at least part of a hand of a user and further configured to couple to the one or more rotatable elements. In some examples, the holding assembly can be similar or the same as holding assembly 130 of FIG. 1.

Next, method 2000 of FIG. 20 includes an activity 2063 of providing a filler cap configured to couple to the one or more rotatable elements. In some examples, the filler cap can be similar or identical to filler cap 1930 of FIG. 19.

Method 2000 in FIG. 20 continues with an activity 2064 of coupling the one or more rotatable elements to the body such that the at least one holding assembly is rotatable when the at least one holding assembly is coupled to the one or more rotatable elements. In various embodiments, the holding assembly is rotatable at least ninety degrees relative to the body when the at least one holding assembly is coupled to the one or more rotatable elements. In some examples, the rotatable element can be coupled to the body similar or identical to the coupling of body 110 to rotatable elements 320 as shown in FIGS. 1-11 and 14 and/or the coupling of body 1210 to rotatable elements 1220 as shown in FIG. 12.

In some examples, activity 2064 can include coupling the one or more rotatable elements to the body such that the at least a part of the one or more rotatable elements and the at least one holding assembly and/or the filler cap are rotatable at least approximately ninety degrees, approximately one hundred and eighty degrees, approximately two hundred and seventy degrees, and/or approximately three hundred and sixty degrees relative to the body.

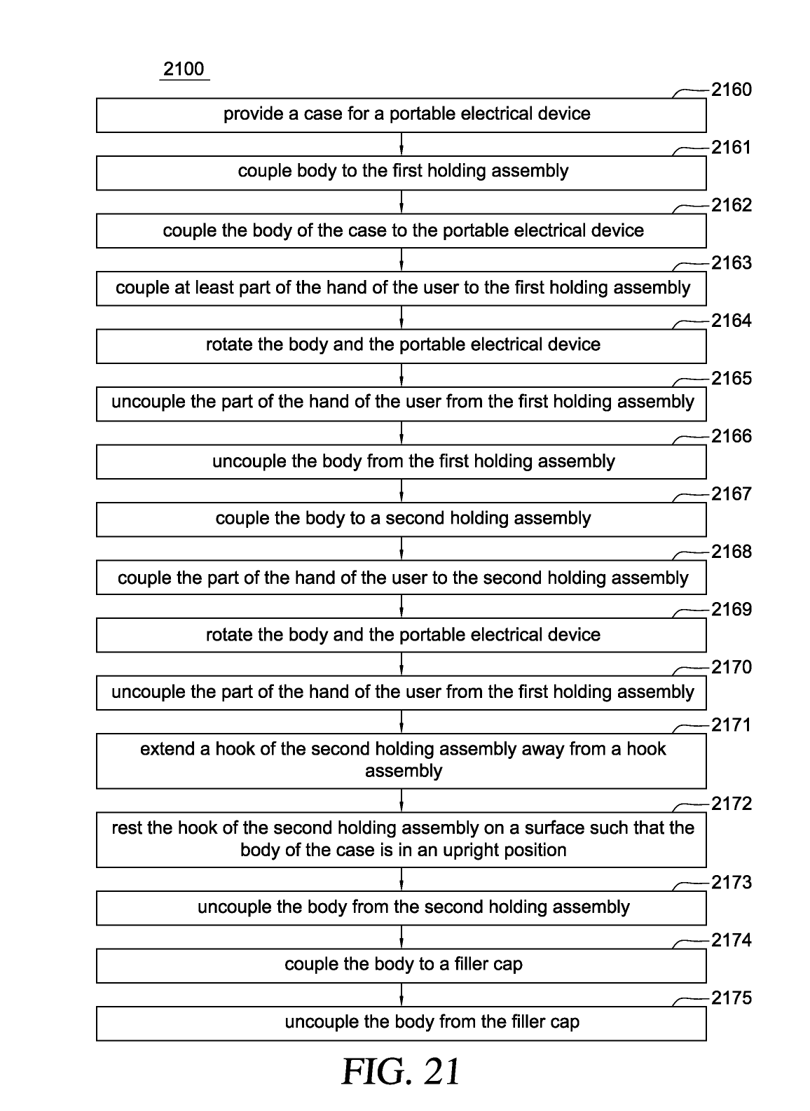

Turning to another embodiment, FIG. 21 illustrates a flow chart for an embodiment of a method 2100 of using a case with a portable electrical device, according to an embodiment. Method 2100 is merely exemplary and is not limited to the embodiments presented herein. Method 2100 can be employed in many different embodiments or examples not specifically depicted or described herein. In some embodiments, the activities, the procedures, and/or the processes of method 2100 can be performed in the order presented. In other embodiments, the activities, the procedures, and/or the processes of the method 2100 can be performed in any other suitable order. In still other embodiments, one or more of the activities, the procedures, and/or the processes in method 2100 can be combined or skipped.

Referring to FIG. 21, method 2100 includes an activity 2160 of providing a case for a portable electrical device. In some examples, the case can be similar or identical to case 100, 1200, 1300, or 1900 of FIGS. 1, 12, 13, and 19, respectively.

In various embodiments, the case can include a body and a holding assembly. The holding assembly can be configured to couple to at least part of a hand of a user. In some examples, the body can be similar or identical to body 110 and/or 1210 of FIGS. 1 and 12, respectively. The holding assembly can be similar or identical to holding assembly 130 or 1350 of FIGS. 1 and 13, respectively.

Method 2100 in FIG. 21 continues with an activity 2161 of coupling the body to the first holding assembly. For example, the coupling of the body to the first holding assembly can be similar or identical to the coupling of body 110 to holding assembly 130, as illustrated in FIGS. 1, 4-7, and 11. The coupling of the body to the first holding assembly can also be similar or identical to the coupling of body 1210 to holding assembly 130 of FIG. 12. The coupling of the body to the first holding assembly can further be similar or identical to the coupling of body 110 to holding assembly 1350, as illustrated in FIGS. 13, 15, and 17.

Subsequently, method 2100 of FIG. 21 includes an activity 2162 of coupling the body of the case to the portable electrical device. For example, the coupling of the body to the portable electrical device can be similar or identical to the coupling of body 110 to portable electrical device 290, as illustrated in FIG. 2. The coupling of the body to the portable electrical device can also be similar or identical to the coupling of body 1210 of FIG. 12 to portable electrical device 290 of FIG. 2. The coupling of the body to the portable electrical device can further be similar or identical to the coupling of body 110 to portable electrical device 290, as illustrated in FIG. 16.

Next, method 2100 of FIG. 21 includes an activity 2163 of coupling at least part of the hand of the user to the first holding assembly. In some examples, the first holding assembly can be coupled to, for example, one to four fingers of the hand of the user, the knuckle of the hand of the user, the palm of the user, and/or the whole hand of the user. FIG. 22 illustrates an example of the first holding assembly coupled to at least part of the hand of the user, according to an embodiment.

Method 2100 in FIG. 21 continues with an activity 2164 of rotating the body and the portable electrical device. In some examples, the portable electrical device and the body can be rotated relative to the first holding assembly. In some examples, the body and the portable electrical device can be rotated at least ninety degrees relative to the first holding assembly. In the same or different examples, the body and the portable electrical device can be rotated at least one hundred and eighty degrees, two hundred and seventy degrees, and/or three hundred and sixty degrees relative to the body. FIG. 23 illustrates an example of a case coupled to at least part of the hand of the user and the electrical device before the body and electrical device are rotated, according to an embodiment. FIG. 24 illustrates an example of a case coupled to at least part of the hand of the user and the electrical device after the body and electrical device have been rotated, according to an embodiment. In this example, the portable electrical device and body have been rotated approximately ninety degrees between the view shown in FIG. 23 and the view shown in FIG. 24.

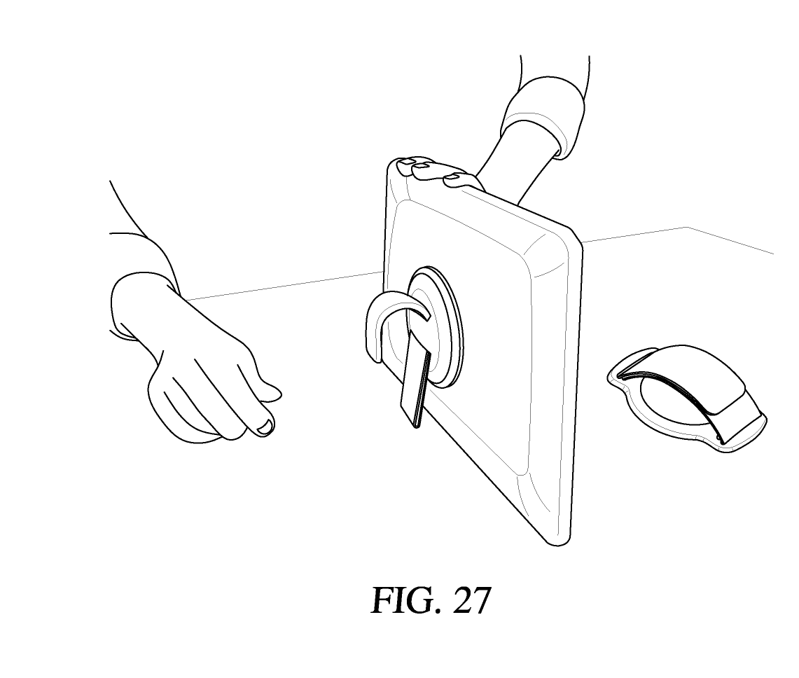

Subsequently, referring back to FIG. 21, method 2100 includes an activity 2165 of uncoupling the part of the hand of the user from the first holding assembly. FIG. 25 illustrates an example of the first holding assembly being uncoupled from the hand of the user, according to an embodiment.

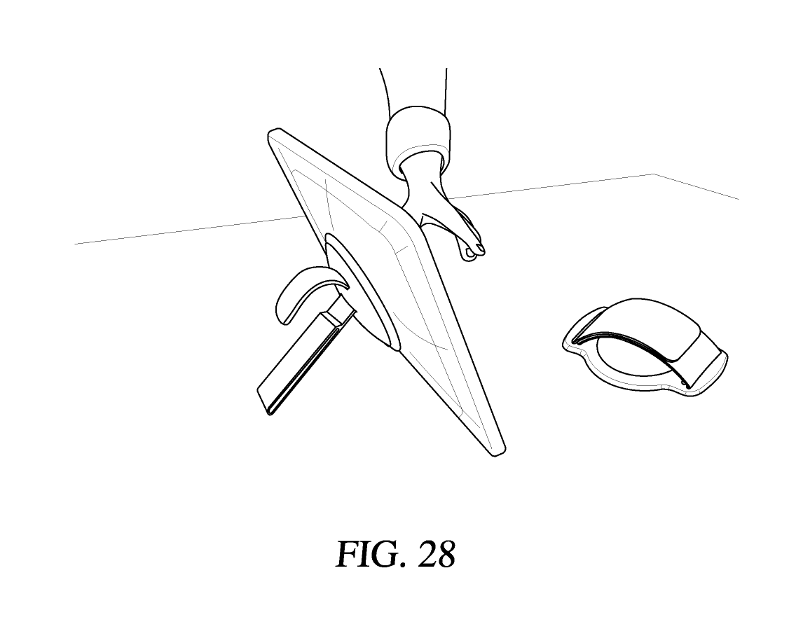

Referring again to FIG. 21, method 2100 continues with an activity 2166 of uncoupling the body from the first holding assembly. In some examples, the first holding assembly can be snapped off a back side of the body. FIG. 26 illustrates an example of the first holding assembly being uncoupled from the body, according to an embodiment.

Furthermore, the body uncoupled from the first holding assembly can be similar or identical to body 110 uncoupled from holding assembly 130, as shown in FIG. 3. The body uncoupled from the first holding assembly can also be similar or identical to body 110 of FIG. 12 uncoupled from holding assembly 130 of FIG. 12. Furthermore, the body uncoupled from the first holding assembly can be similar or identical to body 110 uncoupled from holding assembly 1350 as shown in FIG. 14.

Next, method 2100 of FIG. 21 includes an activity 2167 of coupling the body to a second holding assembly. In some examples, activity 2167 can be similar or identical to activity 2161. In the same or different examples, the first holding assembly can be the same as or similar to holding assembly 130 (FIG. 1), and the second holding assembly can be similar to holding assembly 1350 (FIG. 13), or vice versa.

Method 2100 in FIG. 21 continues with an activity 2168 of coupling a part of the hand of the user to the second holding assembly. In some examples, activity 2168 can be similar or identical to activity 2163.

Subsequently, method 2100 of FIG. 21 includes an activity 2169 of rotating the body and the portable electrical device when the second holding assembly is coupled to the body. In some examples, activity 2169 can be similar or identical to activity 2164.

Next, method 2100 of FIG. 21 includes an activity 2170 of uncoupling the part of the hand of the user from the first holding assembly. In some examples, activity 2169 can be similar or identical to activity 2165.

Method 2100 in FIG. 21 continues with an activity 2171 of extending a hook of the second holding assembly away from a hook assembly. In some examples, the second holding assembly can include a hook and a hook assembly. For example, the second holding assembly, the hook, and the hook assembly can be similar or identical to holding assembly 1350, hook 1351, and hook assembly 1350, respectively, of FIG. 13. In various embodiments, the hook can be extended into two or more extended positions.

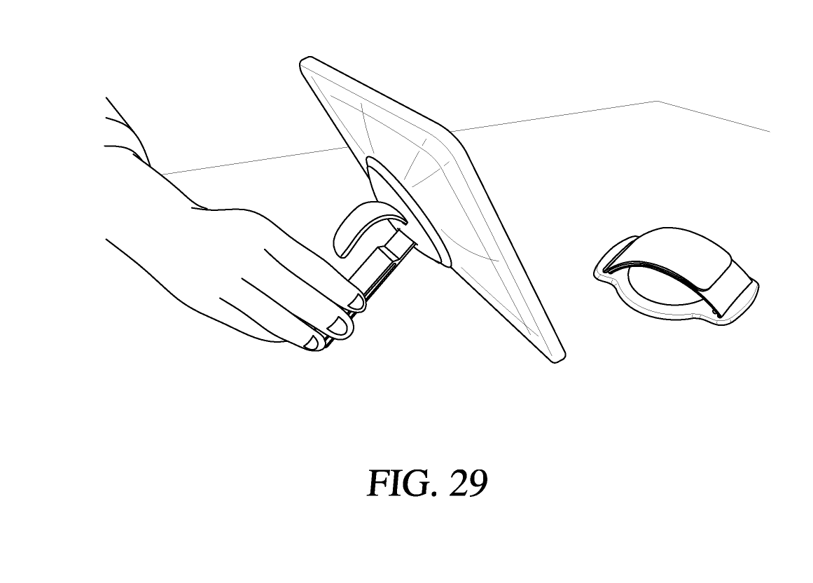

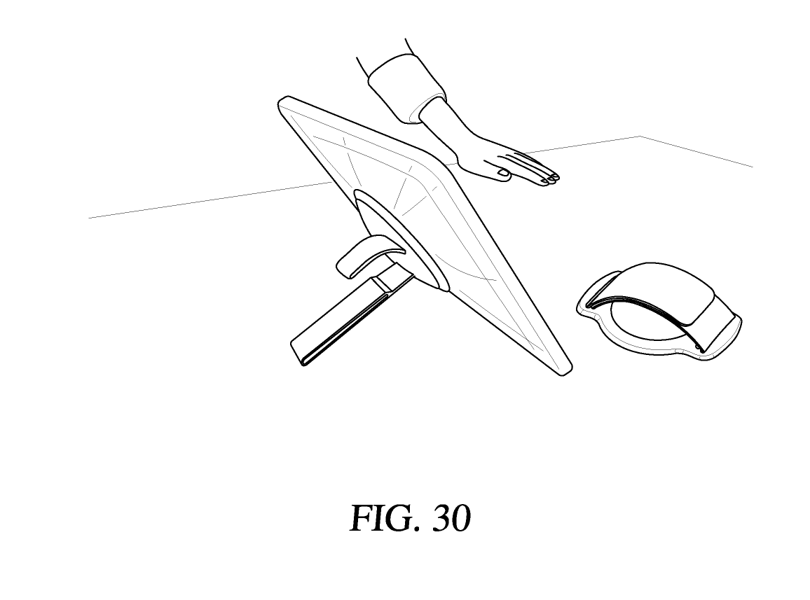

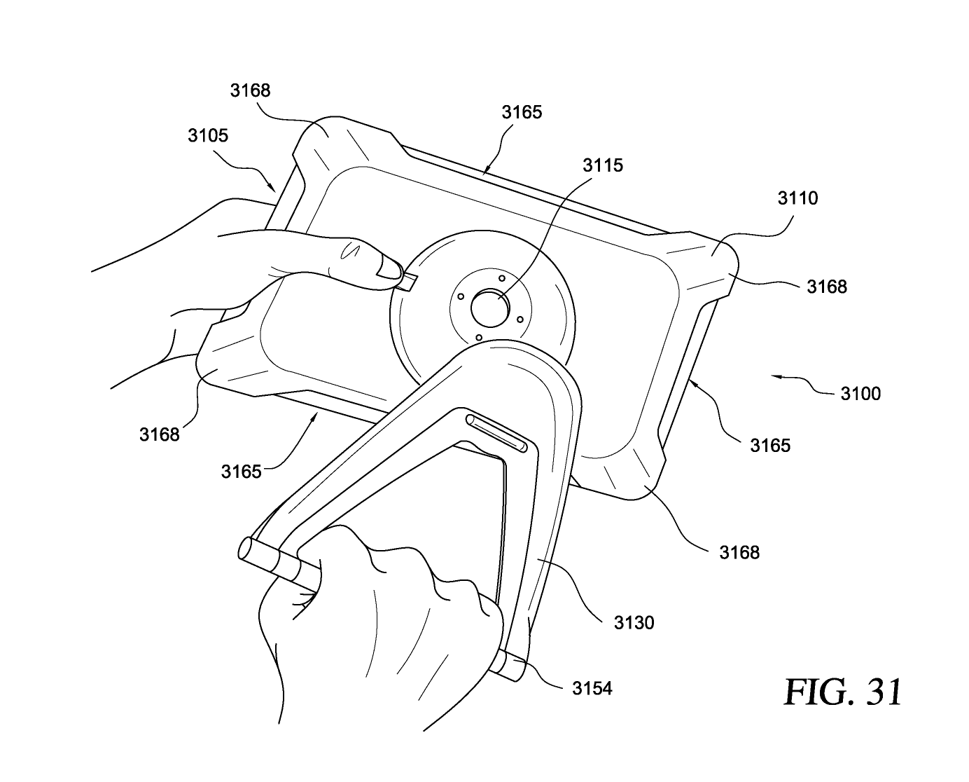

For example, FIG. 27 illustrates an example of the second holding assembly in an unextended position, according to an embodiment. FIG. 28 illustrates an example of the second holding assembly in a first extended position, according to an embodiment. FIG. 29 illustrates an example of the hook of the second holding assembly being extended away from the first hook assembly between the first extended position and a second extended position, according to an embodiment. FIG. 30 illustrates an example of the second holding assembly in a second extended position, according to an embodiment.

Subsequently, referring back to FIG. 21, method 2100 includes an activity 2172 of resting the hook of the first holding assembly on a surface such that the body of the case is in an upright position. FIGS. 16-17, 27, 28, and 30 illustrate exemplary examples of resting the hook of the second holding assembly on a surface such that the body of the case is in an upright position. As used herein, an “upright position” can refer to a position where the top of the electrical device is farther from the surface than the bottom of the electrical device, or a position where one of the right or left side is farther from the surface than the other one of the right or left side.

Next, method 2100 of FIG. 21 includes an activity 2173 of uncoupling the body from the second holding assembly. In some examples, activity 2173 can be similar or identical to activity 2166.

Method 2100 in FIG. 21 continues with an activity 2174 of coupling the body to a filler cap. In some examples, coupling the body to a filler cap can be similar or identical to body 110 of FIG. 19 coupled to filler cap 1930 of FIG. 19.

Then, method 2100 in FIG. 21 continues with uncoupling the body from the filler cap.

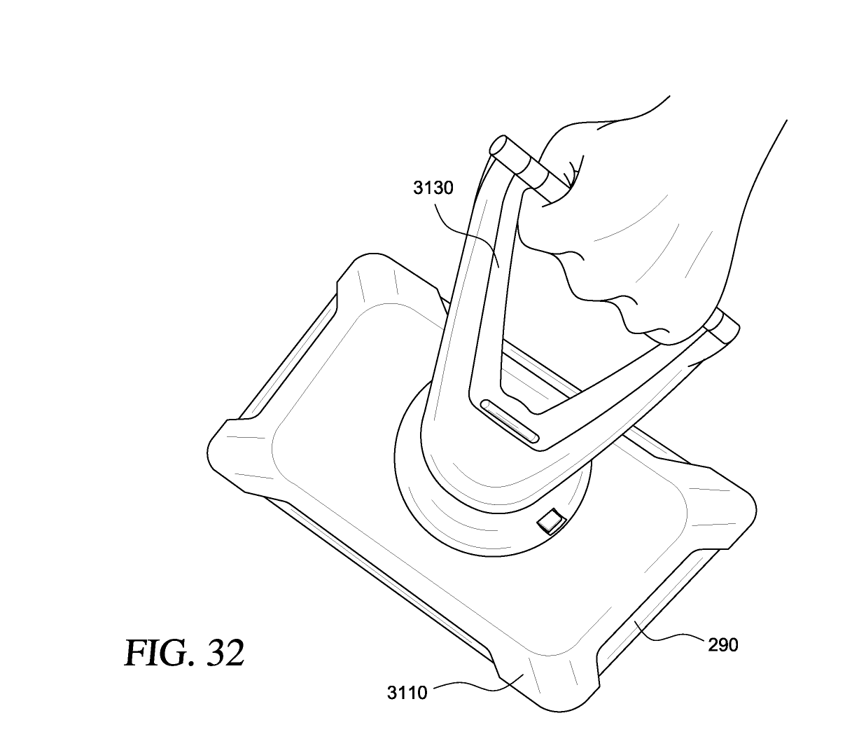

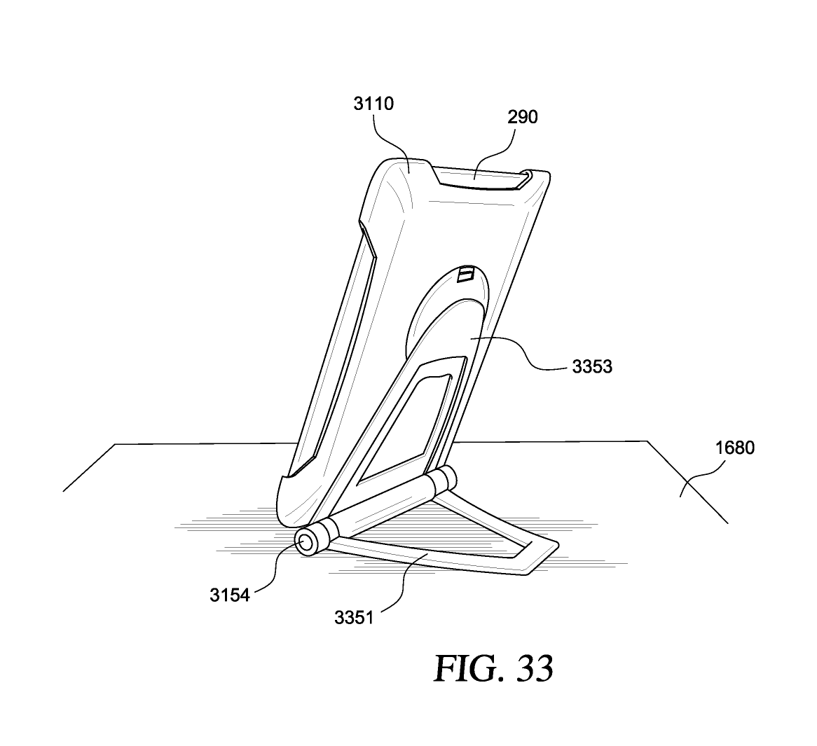

FIG. 31 illustrates a partially exploded, back, right isometric view of a case 3100 being held by a user, according to a fifth embodiment. FIG. 32 illustrates a back view of case 3100 being held by the user, according to the fifth embodiment. FIG. 33 illustrates a back, right isometric view of case 3100 resting on a surface, according to the fifth embodiment. In some examples, case 3100 can be configured to removably couple to portable electrical device 290 (FIG. 2). Case 3100 can also be considered a holder for portable electrical device 290. Case 3100 is merely exemplary and is not limited to the embodiments presented herein. Case 3100 can be employed in many different embodiments or examples not specifically depicted or described herein.

In some examples, case 3100 can include: (a) a body 3110 configured to removably couple to portable electrical device 290 (FIG. 2); (b) a holding assembly 3130 (i.e., a holding mechanism). In some examples, holding assembly 3130 is coupled to body 3110 such that at least holding assembly 3130 is rotatable at least ninety degrees relative to body 3110. In the same or different examples, holding assembly 3130 is coupled to body 3110 such that at least holding assembly 3130 is rotatable at least one hundred and eighty degrees, two hundred and seventy degrees, and/or three hundred and sixty degrees relative to body 3110.

Body 3110 can include one or more edge portions 3168. In some examples, edge portions 3168 can be configured to couple to electrical device 290. Furthermore, body 3110 can also include one or more apertures 3165 and 3115. Aperture 3115 can be located substantially at the center of body 3110 and be circular-shaped. Apertures 3165 can be located at an outer edge of body 3110. In some examples, apertures 3165 can be configured to provide access to one or more controls or buttons on electrical device 290 when electrical device 290 is coupled to body 3110.

In some examples, holding assembly 3130 (i.e., a holding mechanism) can include: (a) a stand 3351; and (b) a stand base 3353 coupled to stand 3351. In some examples, stand 3351 is coupled to stand base 3353 at a joint 3154. Holding assembly 3130 can be configured to removably couple to body 3110 at aperture 3115. In some examples, holding assembly 3130 can include a coupling mechanism (not shown) that is configured to couple to body 3110 at aperture 3115. In some examples, the coupling mechanism is a protrusion extending from holding assembly 3130. In various embodiments, the coupling mechanism can snap into aperture 3115. In other embodiments, other coupling mechanisms can be used to couple holding assembly 3130 to body 3110.

Holding assembly 3130 can be configured such that stand 3351 can be placed in at least a first position and a second position relative to stand base 3353. For example, as shown in FIG. 32, holding assembly 3130 can be configured such that stand 3351 can be placed in a first position relative to stand base 3353 such that at least a part of the hand of a user of electrical device 290 can be removably coupled to stand 3351 and stand base 3353 to removably couple the holding assembly 3130 to the part of the hand of the user. In some examples, stand base 3353 can abut, be adjacent to, or coupled to stand 3351 when in the first position.

As illustrated in FIG. 33, holding assembly 3130 is further configured such that stand 3351 can be placed in a second position relative to stand base 3353 such that stand 3351 can rest on a surface 1680 to at least partially support case 3100 in an upright position.

In some examples, the user can move stand 3351 from the first position to the second position by pulling stand 3351 away from stand base 3353. Similarly, the user can move stand 3351 from the second position to the first position by pushing stand 3351 toward stand base 3353. In some examples, stand 3351 is coupled to stand base 3353 at a joint 3154. In some example, stand 3351 and stand base 3353 can moved relative to one another by rotating stand 3351 at joint 3154.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that activities 2060-2064 of FIG. 20 and activities 2160-2175 of FIG. 21 may be comprised of many different activities, procedures and be performed by many different modules, in many different orders, and that any element of FIGS. 1-19, 22-30, and 31-33 may be modified and that the foregoing discussion of certain of these embodiments does not necessarily represent a complete description of all possible embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims, unless such benefits, advantages, solutions, or elements are stated in such claim.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A holder for an electrical device, the electrical device comprising a front with a screen, one or more sides with one or more side controls, and a back opposite the front, the holder comprising:
a cover configured to couple to the electrical device, the cover comprising:
a front portion;
a back portion opposite the front portion;
one or more side portions; and
a holding mechanism coupled to the back portion of the cover such that the holding mechanism is rotatable at least ninety degrees relative to the back portion of the cover, the holding mechanism comprising:
a strap assembly configured to couple to the back portion of the cover; and
a strap configured to couple to the strap assembly,
wherein:
the back portion has a substantially circular aperture;
at least a first portion of the strap assembly has a substantially circular shape;
the at least the first portion of the strap assembly is configured to couple to the cover at the substantially circular aperture of the back portion;
the holding mechanism is configured to rotate relative to the back portion of the cover such that the at least the first portion of the strap assembly is rotatable at least approximately ninety degrees around the substantially circular aperture of the back portion;
the holding mechanism is further configured such that at least a part of a hand of a user of the electrical device can slide between the strap assembly and the strap to removably couple the holding mechanism to the at least the part of the hand of the user of the electrical device;
the one or more side portions are configured such that the one or more side controls of the electrical device are accessible to the user when the cover is coupled to the electrical device;
the cover is configured such that the screen of the electrical device is accessible to the user when the cover is coupled to the electrical device; and
the cover is configured such that the front portion of the cover is adjacent to the back of the electrical device when the cover is coupled to the electrical device.

2. The holder of claim 1, wherein:
the holding mechanism is coupled to the back portion of the cover such that the holding mechanism is rotatable at least three hundred and sixty degrees relative to the back portion of the cover.

3. The holder of claim 1, wherein:
the holding mechanism is removably coupleable to at least one of:
one or more fingers of the hand of the user of the electrical device, the at least the part of the hand of the user of the electrical device comprises the one or more fingers of the hand of the user of the electrical device;
one or more knuckles and one or more fingers of the hand of the user of the electrical device, the at least the part of the hand of the user of the electrical device comprises the one or more knuckles and the one or more fingers of the hand of the user of the electrical device; or
a palm of the hand of the user of the electrical device, the at least the part of the hand of the user of the electrical device comprises the palm of the hand of the user of the electrical device.

4. The holder of claim 1, further comprising:
a hook mechanism removably coupleable to the back portion of the cover such that the hook mechanism is rotatable at least ninety degrees relative to the back portion of the cover, the hook mechanism comprises:
a hook assembly configured to removably couple to the back portion of the cover at the substantially circular aperture; and
a hook coupled to the hook assembly, the hook has a substantially J-shape,
wherein:
the hook mechanism is configured to couple to the at least the part of the hand of the user of the electrical device;
the hook assembly is removably coupleable to the back portion of the cover when the holding mechanism is not coupled to the back portion of the cover; and
the strap assembly is removably coupleable to the back portion of the cover when the hook assembly is not coupled to the back portion of the cover.

5. The holder of claim 4, wherein:
the hook mechanism is configured such that the hook can be placed in a first position relative to the hook assembly such that the at least the part of the hand of the user of the electrical device is removably coupleable to the hook; and
the hook mechanism is further configured such that the hook can be placed in one or more second positions relative to the hook assembly such that the hook can rest on a surface to at least partially support the holder in an upright position.

6. The holder of claim 1, further comprising:
at least one first ring assembly coupled to the cover, the at least one first ring assembly comprises:
a base portion coupled to the cover; and
one or more rotatable portions coupled to the base portion such that the one or more rotatable portions and the holding mechanism are rotatable at least ninety degrees relative to the cover and the base portion.

7. The holder of claim 6, further comprising:
at least one second ring assembly coupled to the cover and the base portion such that the at least one second ring assembly is substantially immobile relative to the cover.

8. A case configured to removably couple to a portable electrical device, the portable electrical device having a front side with a screen, a left side coupled to the front side, a right side coupled to the front side and a back side opposite the front side and coupled to the left side and the right side, the case is configured to coupled to at least part of a hand of a user of the portable electrical device, the case comprising:
a body configured to removably couple to the portable electrical device;
a holding assembly coupled to the body, the holding assembly comprises:
a first coupling assembly configured to couple to the body; and
a hand coupling assembly coupled to the first coupling assembly and configured to removably couple to the at least the part of the hand of the user of the portable electrical device,
wherein:
at least a portion of the first coupling assembly is substantially circular-shaped;
the body comprises:
a back side with a first substantially circular aperture; and
a front side opposite the back side;
the at least the portion of the first coupling assembly that is substantially circular-shaped is removably coupled to the body at the first substantially circular aperture of the back side of the body;
the holding assembly is coupled to the body such that the holding assembly is rotatable at least ninety degrees relative to the body and the portable electrical device when the body is coupled to the portable electrical device and when the body is coupled to the holding assembly;
the holding assembly is further configured such that the at least the part of the hand of the user of the portable electrical device can slide into the holding assembly to removably couple the holding assembly to the at least the part of the hand of the user of the portable electrical device; and
the body is configured to couple to the portable electrical device such that the screen of the portable electrical device is useable when the body is coupled to the portable electrical device and when the back side of the portable electrical device is adjacent to the front side of the body.

9. The case of claim 8, wherein:
the holding assembly is configured such that the hand coupling assembly can be placed in a first position relative to the body such that the at least the part of the hand of the user of the portable electrical device is removably coupleable to the holding assembly; and
the holding assembly is further configured such that the holding assembly can be placed in one or more second positions relative to the body such that at least a portion of the holding assembly can rest on a surface to at least partially support the case in an upright position.

10. The case of claim 8, wherein:
the first coupling assembly comprises at least one of:
a stand assembly, the hand coupling assembly comprises a stand, and the holding assembly is configured such that the stand can be extended away from the stand assembly into one or more extended positions; or
a strap assembly configured to couple to the back side of the body, the hand coupling assembly comprises a strap configured to couple to the strap assembly.

11. The holder of claim 8, wherein:
the holding assembly is coupled to the body such that the holding assembly is rotatable at least three hundred and sixty degrees relative to the body and the portable electrical device when the body is coupled to the portable electrical device.

12. The case of claim 8, wherein:
the holding assembly is removably coupled to the body.

13. The case of claim 8, wherein:
the body further comprises:
one or more rotatable elements coupled to the back side of the body, the one or more rotatable elements comprise:
a base portion; and
one or more rotatable portions configured to couple to the holding assembly,
wherein:
the holding assembly is removably coupleable to the one or more rotatable portions of the one or more rotatable elements of the body such that the holding assembly and the one or more rotatable portion of the one or more rotatable elements of the body are rotatable at least three hundred and sixty degrees relative to the body and the portable electrical device when the body is coupled to the portable electrical device and when the body is coupled to the holding assembly; and
the base portion of the one or more rotatable elements of the body is configured to be substantially immobile when the one or more rotatable portions of the one or more rotatable elements of the body are rotated.

14. A method of providing a case for a portable electrical device, the portable electrical device having a front side with a screen, a left side coupled to the front side, a right side coupled to the front side and a back side opposite the front side and coupled to the left side and the right side, the case is configured to removably couple to at least part of a hand of a user of the portable electrical device, the method comprising:
providing a body configured to removably couple to the portable electrical device, the body comprising:
a front side;
a back side opposite the front side and having a first substantially circular aperture, wherein the body is configured to couple to the portable electrical device such that the screen of the portable electrical device is useable when the body is coupled to the portable electrical device and the back side of the portable electrical device is adjacent to the front side of the body;
providing a holding assembly configured such that the at least the part of the hand of the user of the portable electrical device can slide into the holding assembly to removably couple the holding assembly to the at least the part of the hand of the user of the portable electrical device, the holding assembly comprises:
a first coupling assembly coupled to the body wherein the first coupling assembly comprises at least a substantially circular-shaped portion; and
a hand coupling assembly coupled to the first coupling assembly and configured to removably couple to the at least the part of the hand of the user of the portable electrical device; and
coupling the holding assembly to the body by coupling the at least the substantially circular-shaped portion of the first coupling assembly of the holding assembly to the body at the first substantially circular aperture of the back side of the body and such that the holding assembly is rotatable at least ninety degrees relative to the body.

15. The method of claim 14, further comprising:
providing a filler cap configured to couple to the body when the holding assembly is not coupled to the body,
wherein:
coupling the holding assembly to the body comprises:
removably coupling the holding assembly to the body by coupling the at least the substantially circular-shaped portion of the first coupling assembly of the holding assembly to the body at the first substantially circular aperture of the back side of the body.

16. The method of claim 14, wherein:
coupling the holding assembly to the body comprises:
coupling the holding assembly to the body by coupling the at least the substantially circular-shaped portion of the first coupling assembly of the holding assembly to the body at the first substantially circular aperture of the back side of the body and such that the holding assembly is rotatable at least three hundred and sixty degrees relative to the body.

17. The method of claim 14, wherein:
providing the holding assembly comprises at least one of:
providing a first holding assembly comprising: a strap assembly configured to removably couple to the body; and a strap configured to removably couple to the strap assembly, the hand coupling assembly comprising the strap and the first coupling assembly comprising the strap assembly; or
providing a second holding assembly comprising: a hook assembly configured to removably couple to the body; and a hook configured to removably couple to the hook assembly, the hand coupling assembly comprising the hook and the first coupling assembly comprising the hook assembly.

18. A method of using a case with a portable electrical device, the case comprising a body and a first holding assembly, the first holding assembly configured to couple to at least a part of a hand of a user, the method comprising:
coupling the body of the case to the portable electrical device;
coupling the body to the first holding assembly;
coupling at least part of the hand of the user to the first holding assembly; and
rotating the body and the portable electrical device at least ninety degrees relative to the first holding assembly.

19. The method of claim 18, further comprising:
uncoupling the at least the part of the hand of the user from the first holding assembly;
extending a stand of the first holding assembly away from a stand assembly of the first holding assembly; and
resting the stand of the first holding assembly on a surface such that the body of the case is in an upright position.

20. The method of claim 18, further comprising:
uncoupling the at least the part of the hand of the user from the first holding assembly;
uncoupling the body from the first holding assembly;
coupling the body to a second holding assembly;
coupling the at least the part of the hand of the user to the second holding assembly; and
rotating the body and the portable electrical device at least ninety degrees relative to the second holding assembly,
wherein:
the first holding assembly comprises:
a strap assembly; and
a strap configured to couple to the strap assembly; and
the second holding assembly comprises:
a stand assembly; and
a substantially J-shaped stand coupled to the stand assembly.
